(19) United States
(12) Patent Application Publication
(10) Pub. No.: US 2026/0047226 A1
(43) Pub. Date: Feb. 12, 2026

(54) IMAGE SENSOR AND METHOD OF FABRICATING THE SAME

(71) Applicant: SAMSUNG ELECTRONICS CO., LTD., Suwon-si (KR)

(72) Inventors: Sehoon YOO, Suwon-si (KR); Donghyun KIM, Suwon-si (KR); Woobin BAE, Suwon-si (KR); Seungjae LEE, Suwon-si (KR); Hakjin LEE, Suwon-si (KR); Minjun CHOI, Suwon-si (KR)

(73) Assignee: SAMSUNG ELECTRONICS CO., LTD., Suwon-si (KR)

(21) Appl. No.: 19/024,497

(22) Filed: Jan. 16, 2025

(30) Foreign Application Priority Data
Aug. 12, 2024 (KR) 10-2024-0107668
Sep. 6, 2024 (KR) 10-2024-0121667

(51) Int. Cl. H10F 39/00

(52) U.S. Cl. CPC H10F 39/809; H10F 39/8057; H10F 39/806; H10F 39/811

(57) ABSTRACT

An image sensor includes a stack structure including an active pixel region including a plurality of pixels, a pad region on at least one side of the active pixel region, and a first substrate having a first surface and a second surface that is opposite to the first surface, the first substrate including a plurality of photoelectric conversion regions respectively corresponding to the plurality of pixels, a meta-optical structure on the first surface of the first substrate and including a plurality of dielectric layers on the first surface of the first substrate, and nanoprism patterns in at least one dielectric layer of the plurality of dielectric layers and in the active pixel region, a pad opening in the meta-optical structure and a passivation layer at least partially covering a sidewall of the pad opening.

### CROSS-REFERENCE TO RELATED APPLICATION(S)

This application is based on and claims priority to Korean Patent Application No. 10-2024-0121667 filed on Sep. 6, 2024, and Korean Patent Application No. 10-2024-0107668, filed on Aug. 12, 2024, in the Korean Intellectual Property Office, the disclosures of which are incorporated by reference herein in their entireties.

### BACKGROUND

Example embodiments of the disclosure relate to an image sensor and method of fabricating the same.

An image sensor may be a semiconductor-based sensor, which may receive light by position/color from images formed by an optical structure to generate electrical signals. As the optical structure of the image sensor, microlenses and color filters may be used in each pixel, but as the demand for high-resolution cameras increases, pixels are becoming increasingly microscopic, and the size of optical structures is gradually reduced. However, this miniaturization of optical structures may decrease the optical efficiency of the image sensor.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an image sensor that may be capable of having improved reliability, and a method of fabricating the same.

Additional aspects will be set forth in part in the description which follows and, in part, will be apparent from the description, or may be learned by practice of the presented embodiments.

According to an aspect of an example embodiment, an image sensor may include a stack structure including an active pixel region including a plurality of pixels, a pad region on at least one side of the active pixel region, and a first substrate having a first surface and a second surface that is opposite to the first surface, the first substrate including a plurality of photoelectric conversion regions respectively corresponding to the plurality of pixels, a meta-optical structure on the first surface of the first substrate and including a plurality of dielectric layers on the first surface of the first substrate, and nanoprism patterns in at least one dielectric layer of the plurality of dielectric layers and in the active pixel region, a pad opening in the meta-optical structure and a passivation layer at least partially covering a sidewall of the pad opening.

According to an aspect of an example embodiment, an image sensor may include a stack structure including an active pixel region including a plurality of pixels, a pad region on at least one side of the active pixel region, a first substrate having a first surface and including a plurality of photoelectric conversion regions respectively corresponding to the plurality of pixels, a meta-optical structure on the first surface of the first substrate and including a plurality of dielectric layers on the first surface of the first substrate, and nanoprism patterns in at least one dielectric layer of the plurality of dielectric layers and in the active pixel region, and a pad opening in the meta-optical structure, where the nanoprism patterns include a first nanoprism pattern and a second nanoprism pattern, the plurality of dielectric layers include a first molded layer having the first nanoprism pattern therein, and a second molded layer on the first molded layer and having the second nanoprism pattern therein, the first molded layer includes a first edge portion spaced apart from a sidewall of the pad opening, and the second molded layer covers the first edge portion of the first molded layer.

According to an aspect of an example embodiment, an image sensor may include a stack structure including an active pixel region including a plurality of pixels, a pad region on at least one side of the active pixel region, and a first substrate having a first surface and including a plurality of photoelectric conversion regions respectively corresponding to the plurality of pixels, a meta-optical structure on the first surface of the first substrate and including a plurality of dielectric layers on the first surface of the first substrate, and nanoprism patterns in at least one dielectric layer of the plurality of dielectric layers and in the active pixel region, a pad opening in the meta-optical structure, and a transparent planarization layer between the first surface of the first substrate and the meta-optical structure, the transparent planarization layer including an edge portion spaced apart from a sidewall of the pad opening, where the edge portion of the transparent planarization layer is covered by at least one of the plurality of dielectric layers.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is an exploded perspective view illustrating an image sensor according to one or more embodiments;

FIG. 2 is a plan view of region “A” of the image sensor of FIG. 1 according to one or more embodiments;

FIG. 3 is a cross-sectional view taken along line I-I′ of the region of FIG. 2 according to one or more embodiments;

FIG. 4 is a cross-sectional view illustrating an image sensor according to one or more embodiments;

FIGS. 5A to 5G are cross-sectional views illustrating a method of fabricating an image sensor according to one or more embodiments;

FIGS. 6 and 7 are cross-sectional views illustrating an image sensor according to one or more embodiments;

FIGS. 8A to 8D are cross-sectional views illustrating a method of fabricating an image sensor according to one or more embodiments;

FIGS. 9 to 11 are cross-sectional views illustrating an image sensor according to one or more embodiments;

FIGS. 12A to 12E are cross-sectional views illustrating a method of fabricating an image sensor according to one or more embodiments;

FIGS. 13 and 14 are cross-sectional views illustrating an image sensor according to one or more embodiments;

FIGS. 15A to 15C are cross-sectional side views illustrating a method of fabricating an image sensor according to one or more embodiments; and

FIGS. 16 and 17 are cross-sectional views illustrating an image sensor according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

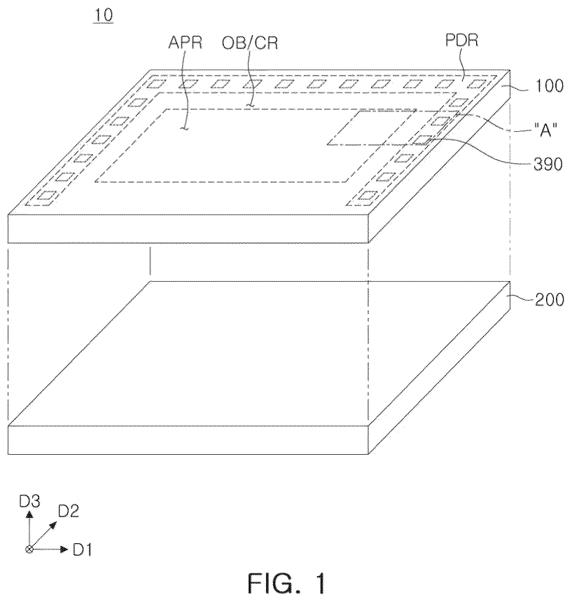

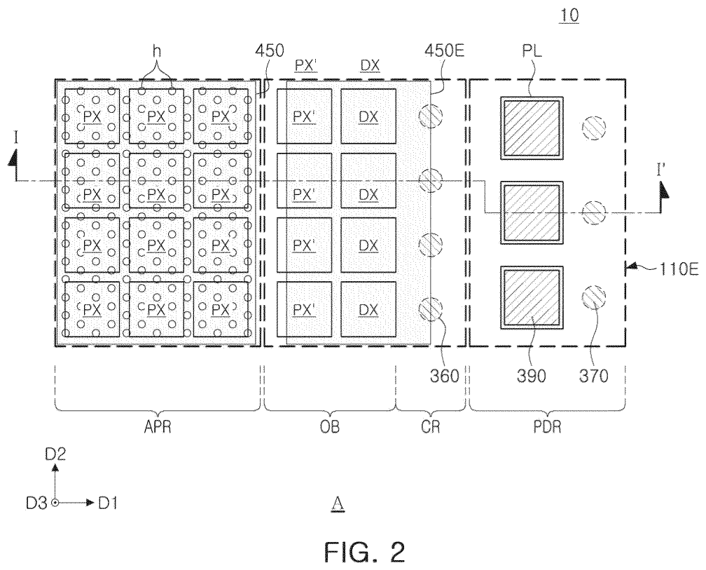

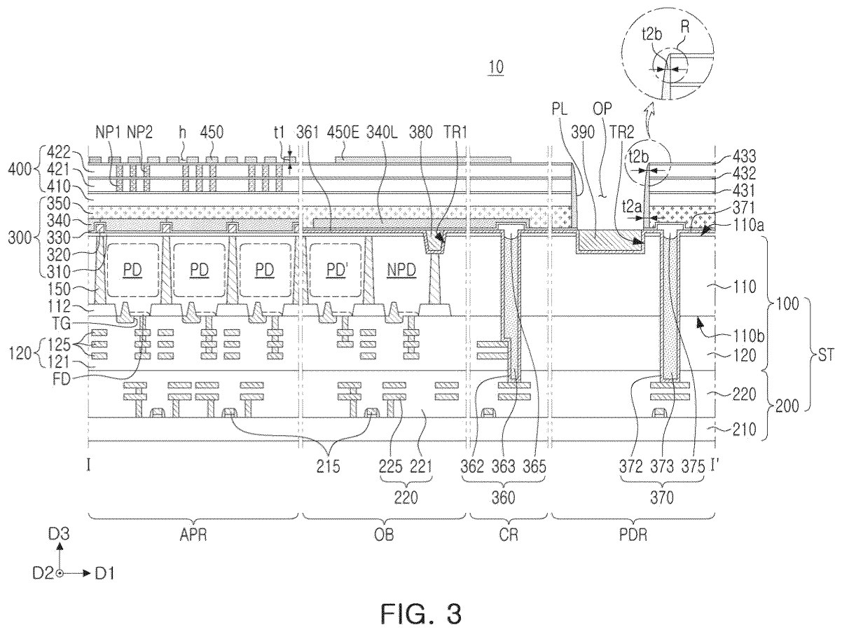

FIG. 1 is an exploded perspective view illustrating an image sensor according to one or more embodiments. FIG. 2 is a plan view of region “A” of the image sensor of FIG. 1 according to one or more embodiments. FIG. 3 is a cross-sectional view taken along line I-I′ of the region of FIG. 2 according to one or more embodiments.

Referring to FIGS. 1 to 3, an image sensor 10 according to one or more embodiments may include a stack structure ST in which a first substrate structure 100 and a second substrate structure 200 are stacked and electrically connected to each other. The stack structure ST in one or more embodiments may include an active pixel region APR in which a plurality of pixels PX are arranged, a pad region PDR disposed on at least one side of the active pixel region APR, and an optical black region OB and a connection region CR between the active pixel region APR and the pad region PDR.

As illustrated in FIG. 1, an active pixel region APR may be disposed in a central portion of the stack structure ST. The plurality of pixels PX may be disposed in the active pixel region APR. The plurality of pixels PX may be arranged in a matrix shape by forming rows and columns in a first substrate 110 in a first direction D1, and a second direction D2, intersecting the first direction D1, in the active pixel region APR. Each of the plurality of pixels PX may include at least one photoelectric conversion region PD formed in the first substrate 110. The plurality of pixels PX may be a region receiving light from the outside of the stack structure ST and converting the light into an electrical signal. For example, the plurality of pixels PX may include a photoelectric conversion region PD for receiving external light, and transistors included in a pixel circuit for converting photocharges accumulated in the photoelectric conversion region PD into an electrical signal.

The pad region PDR may be disposed on at least one side of the active pixel region APR, for example, on three sides of the active pixel region APR, as illustrated in FIG. 1. A plurality of bonding pads 390 may be disposed in the pad region PDR and configured to transmit and receive electrical signals with an external device, or the like.

The optical black region OB and the connection region CR may be sequentially arranged around the active pixel region APR between the active pixel region APR and the pad region PDR. The optical black region OB may correspond to a region in which light is blocked and may include optical black pixels PX′ generating a dark signal to function as a reference pixel for the active pixel region APR, and dummy pixels DX may be further disposed around the optical black pixels PX′ (see FIG. 2). The connection region CR may be arranged on one side of the optical black region OB, but this is only an example. The connection region CR may be configured to transmit and receive the electrical signal of the photoelectric conversion region PD to and from a circuit of a second substrate 210 by connecting a first interconnection structure 120 and a second interconnection structure 220 by first connection structures 360.

As described above, referring to FIG. 3, the image sensor 10 according to one or more embodiments may include the stack structure ST having the first substrate structure 100 and the second substrate structure 200.

The first substrate structure 100 may include a first substrate 110 having a first surface 110a and a second surface 110b disposed opposite to each other, a front optical structure 300 on the first surface 110a of the first substrate 110, and a first interconnection structure 120 on the second surface 110b of the first substrate 110. The second substrate structure 200 may include a second substrate 210 having an upper surface on which logic elements 215 are disposed, and a second interconnection structure 220 contacting the first interconnection structure 120 on the second substrate 210. The first substrate structure 100 may also be referred to as a ‘sensor chip,’ and the second substrate structure 200 may also be referred to as a ‘logic chip.’ The image sensor 10 according to one or more embodiments is exemplified as a stack structure having two substrates, but is not limited thereto, and in one or more embodiments, an image sensor 10 may include a stack structure having three substrates. For example, transistors for pixel circuits implemented on the first substrate 110 may be implemented as separate intermediate plates.

The image sensor 10 according to one or more embodiments may include a meta-optical structure 400, for example, instead of an optical lens. Here, the meta-optical structure 400 may refer to an optical structure based on meta-optics, and may also be referred to as a meta-surface or a meta-lens. In one or more embodiments, the meta-optical structure 400 may be disposed on the first surface 110a of the first substrate 110, which is an incident surface side, and may be configured to disperse incident light according to wavelength (e.g., color) and focus the dispersed light onto the photoelectric conversion region PD of different pixels PX.

Referring to FIG. 3, the meta-optical structure 400 may be a multilayer structure including a plurality of dielectric layers 410, 421 and 422, and may include nanoprism patterns NP1 and NP2 (e.g., nano-scale structures (e.g., post structures)) arranged in at least one dielectric layer 421 or 422, among the plurality of dielectric layers. In one or more embodiments, the nanoprism patterns NP1 and NP2 may be disposed in an overlapping region in the active pixel region APR. The plurality of dielectric layers 410, 421 and 422 may extend to the pad region PDR by passing not only through the active pixel region APR but also through the optical black region OB and the connection region CR.

In one or more embodiments, a pad opening OP for opening a bonding pad 390 may be formed in a portion of the meta-optical structure 400 extending to the pad region PDR. The portion extending to the pad region PDR may include only a plurality of dielectric layers 410, 421 and 422 without nanoprism patterns NP1 and NP2. Since an interface of the plurality of dielectric layers 410, 421 and 422 and/or an interface of the meta-optical structure 400 and a transparent planarization layer 350 is exposed on an internal sidewall of the pad opening OP, there may be reliability-related problems in that peeling and cracking may occur due to mechanical impact or moisture absorption in a subsequent process, or undercut may occur by over-etching the transparent planarization layer 350 during the formation of the pad opening OP.

In order to prevent such problems, the image sensor 10 according to one or more embodiments may include a passivation layer PL disposed on the internal sidewall of the pad opening OP. The passivation layer PL may be formed to cover the exposed interfaces of the meta-optical structure 400 and the side surfaces of the transparent planarization layer 350. A detailed structure and arrangement of the meta-optical structure 400 and the passivation layer PL in one or more embodiments will be described below.

Referring to FIG. 3, the first substrate 110 of the first substrate structure 100 may be a semiconductor substrate. For example, the first substrate 110 may be a bulk silicon or a silicon-on-insulator (SOI) substrate.

The first substrate 110 may include a pixel separation pattern 150 defining a plurality of pixels PX. The pixel separation pattern 150 may be formed to surround photoelectric conversion regions PD. At least one photoelectric conversion region PD may be formed in the first substrate 110 in each of the plurality of pixels PX. The photoelectric conversion regions PD may generate charges in proportion to the amount of light incident from the outside. For example, the photoelectric conversion regions PD may be a photo diode, a photo transistor, a photo gate, a pinned photo diode, or an organic photo diode. The photoelectric conversion regions PD may be disposed in the active pixel region APR.

As described above, in the optical black region OB adjacent to the active pixel region APR, a reference photoelectric conversion region PD′ may form a reference pixel RX generating a dark signal for reference to the active pixel region APR. Additionally, a dummy photoelectric conversion region NPD may be provided as a dummy pixel region DX not provided as a photoelectric conversion element. The reference photoelectric conversion region PD′ and the dummy photoelectric conversion region NPD may also be separated by a pixel separation pattern 150.

The pixel separation pattern 150 may have a lattice shape for separating a plurality of pixels PX in a planar view. For example, the pixel separation pattern 150 may penetrate through at least a portion of the first substrate 110. In one or more embodiments, the pixel separation pattern 150 may include a deep trench extending from the second surface 110b to the first surface 110a. The pixel separation pattern 150 may include an insulating liner on a sidewall of the deep trench, and a filling portion filled in the insulating liner. For example, the insulating liner may include silicon oxide, silicon nitride, and/or silicon oxynitride, and the filling portion may include a semiconductor material or a conductive material. For example, the filling portion may include impurity-doped polycrystalline silicon.

An element separation pattern 112 defining an active region may be formed on the second surface 110b of the first substrate 110. Elements for a floating diffusion region FD and a pixel circuit may be formed in the active region. Pixel circuit elements may include circuit elements such as various transistors such as a transfer gate TG. The pixel separation pattern 150 may be connected to the element separation pattern 112, a shallow trench structure. In one or more embodiments, the element separation pattern 112 may be disposed on the pixel separation pattern 150. For example, the element separation pattern 112 may include silicon oxide.

The first interconnection structure 120 may include a first inter-interconnection insulating layer 121 and a plurality of first interconnection lines 125 on the first inter-interconnection insulating layer 121. The number of layers of interconnection lines 125 included in the first interconnection structure 120 illustrated in the drawings and an arrangement thereof are merely exemplary. For example, the first inter-interconnection insulating layer 121 may include at least one of silicon oxide, silicon nitride, silicon oxynitride, and a low-κ material having a lower dielectric constant than silicon oxide. For example, the first interconnection lines 125 may include at least one of tungsten (W), copper (Cu), aluminum (Al), gold (Au), silver (Ag), and alloys thereof.

The second substrate 210 may be a bulk silicon or a silicon-on-insulator (SOI) substrate, similarly to the first substrate 110. The logic elements 215 may be disposed on the second substrate 210. The logic elements 215 may be included in a circuit providing a constant signal to each pixel PX of the active pixel region APR or controlling an output signal from each pixel PX. For example, the logic elements 215 may include various transistors included in a control register block, a timing generator, a ramp signal generator, a row driver, a readout circuit, and/or an input/output buffer (I/O) circuit.

The second interconnection structure 220 may be disposed between the first interconnection structure 120 of the first substrate structure 100 and the second substrate 210. The second interconnection structure 220 may include a second inter-interconnection insulating layer 221 and a plurality of second interconnection lines 225 on the second inter-interconnection insulating layer 221. The number of layers of the interconnection lines 225 included in the second interconnection structure 220 and an arrangement thereof are merely exemplary. The plurality of second interconnection lines 225 may include vias electrically connecting the logic elements 215. For example, the second inter-interconnection insulating layer 221 may include at least one of silicon oxide, silicon nitride, silicon oxynitride, and a low-κ material having a lower dielectric constant than silicon oxide. The second interconnection lines 225 may include at least one of tungsten (W), copper (Cu), aluminum (Al), gold (Au), silver (Ag), and alloys thereof.

In one or more embodiments, the first interconnection structure 120 may be bonded to the second interconnection structure 220. In one or more embodiments, each of the first and second interconnection structures 120 and 220 may include a bonding insulating layer disposed on a surface to be bonded. Additionally, the first and second substrate structures 100 and 200 may be bonded by first and second connection structures 360 and 370 penetrating through the first substrate structure 100 and connected to the second substrate structure 200. The first and second connection structures 360 and 370 may electrically connect the first interconnection structure 120 (e.g., the first interconnection lines 125) and the second interconnection structure 220 (e.g., the second interconnection lines 225) in the connection region CR and the pad region PDR, respectively.

Referring to FIG. 3, the first substrate structure 100 may include a front optical structure 300 disposed on the first surface 110a of the first substrate 110. The front optical structure 300 may include a surface insulating layer 310, a grid pattern 320, a protective film 330, color filters 340, and a transparent planarization layer 350, along with the meta-optical structure 400.

The surface insulating layer 310 may be disposed on the first surface 110a of the first substrate 110. The surface insulating layer 310 may extend to a peripheral region OB/CR and the pad region PDR as well as the active pixel region APR. The surface insulating layer 310 may include an insulating material. For example, the surface insulating layer 310 may include at least one of silicon oxide, silicon nitride, silicon oxynitride, aluminum oxide, hafnium oxide, and combinations thereof, but is not limited thereto. Additionally, the surface insulating layer 310 may be a multilayer. For example, the surface insulating layer 310 may include an aluminum oxide film, a hafnium oxide film, a silicon oxide film, a silicon nitride film, and a hafnium oxide film, which are sequentially stacked on the first surface 110a of the first substrate 110, but the present disclosure is not limited thereto. The surface insulating layer 310 functions as an anti-reflection film, thereby preventing reflection of light incident on the first substrate 110 and improving a light reception rate of the photoelectric conversion region PD.

In the active pixel region, the color filters 340 and the grid pattern 320 between the color filters 340 may be disposed on the surface insulating layer 310. The color filters 340 may be disposed on the surface insulating layer 310. The color filters 340 may be arranged to correspond to each pixel PX of the active pixel region APR. The color filters 340 may have various color filters depending on each pixel. For example, the color filters 340 may include a red color filter, a green color filter, and a blue color filter. In one or more embodiments, the color filters 340 may be arranged in a Bayer pattern. However, this is only an example, and the color filters 340 may include a yellow filter, a magenta filter, and a cyan filter, and may further include a white filter.

The grid pattern 320 may have a grid shape in a planar view. In one or more embodiments, the grid pattern 320 may be disposed to overlap the pixel separation pattern 150 in a vertical direction D3. In one or more embodiments, the grid pattern 320 may include a conductive pattern and a low refractive index pattern. The conductive pattern may prevent charges generated by electrostatic discharge (ESD), or the like, from being accumulated on the surface of the first substrate 110, thereby effectively preventing ESD defects. The low refractive index pattern may improve light collection efficiency by refracting or reflecting light incident obliquely, thereby improving the quality of the image sensor. For example, the conductive pattern may include at least one of titanium (Ti), titanium nitride (TiN), tantalum (Ta), tantalum nitride (TaN), tungsten (W), aluminum (Al), and copper (Cu). Additionally, the low refractive index pattern may include a low refractive index material having a lower refractive index than silicon (Si). For example, the low refractive index pattern may include at least one of silicon oxide, aluminum oxide, tantalum oxide, and a combination thereof.

Referring to FIG. 3, in the peripheral region OB/CR, a first conductive layer 361 and a light-blocking filter layer 340L may be sequentially disposed on the surface insulating layer 310. In one or more embodiments, the light-blocking filter layer 340L may provide an optical black region OB and may be provided as a light-blocking structure blocking light along with the first conductive layer 361. In one or more embodiments, the light-blocking filter layer 340L may be formed along with a portion of the color filters 340. The light-blocking filter layer 340L may have a thickness substantially the same as that of the color filters 340, but is not limited thereto. The light-blocking filter layer 340L may include a blue color filter or a black filter.

Referring to FIG. 3, a bias contact plug 380 and the first conductive layer 361 may be disposed in the optical black region OB. The first conductive layer 361 may cover the surface insulating layer 310 on the first surface 110a of the first substrate 110. Additionally, the first conductive layer 361 may conformally cover an external wall of a first trench TR1, and may be connected to the pixel separation pattern 150. The bias contact plug 380 may fill the first trench TR1. The bias contact plug 380 may include a metallic material (e.g., aluminum). The bias contact plug 380 may be connected to the pixel separation pattern 150 through the first conductive layer 361. A bias may be applied to the pixel separation pattern 150 through the bias contact plug 380.

The first connection structure 360 may be disposed in the connection region CR. The first connection structure 360 may include a first connection layer 362, a first separation pattern 363, and a first capping pattern 365. The first connection structure 360 may penetrate through the first substrate structure 100 and the second substrate structure 200 (specifically, a portion of the second interconnection structure 220), thus electrically connecting the first interconnection structure 120 (e.g., the first interconnection lines 125) and the second interconnection structure 220 (e.g., the second interconnection lines 225) to each other. The first connection layer 362 may include a metallic material (e.g., tungsten). The first connection layer 362 may be formed along with the first conductive layer 361.

A second connection structure 370 and the bonding pad 390 may be disposed in the pad region PDR. A second connection structure 560 may include a second connection layer 372, a second separation pattern 373, and a second capping pattern 375. The second connection structure 370 may penetrate through the first substrate structure 100 and the second substrate structure 200 (specifically, a portion of the second interconnection structure 220), thus electrically connecting the first interconnection structure 120 (e.g., the first interconnection lines 125) and the second interconnection structure 220 (e.g., the second interconnection lines 225) to each other. A second conductive layer 371 may be disposed on the surface insulating layer 310 on the first surface 110a of the first substrate 110, and the second connection layer 372 may extend from the second conductive layer 371. The second conductive layer 371 may conformally cover an internal wall of a second trench TR2. The second conductive layer 371 and the second connection layer 372 may include the same metallic material (for example, tungsten).

In one or more embodiments, the bonding pad 390 may be formed by being filled in the second trench TR2. The bonding pad 390 may include a metallic material (for example, aluminum). The bonding pad 390 may connect the second conductive layer 371 and the second connection structure 370 (specifically, the second connection layer 372) to the second interconnection structure 220 (e.g., the second interconnection lines 225), and the second conductive layer 371 and the second connection structure 370 may be connected to the logic elements 215 of the second substrate 210 through the second interconnection layer. The bonding pad 390 may serve as an electrical connection passage between the image sensor 10 and an external element. For example, an electrical signal generated from the photoelectric conversion regions PD in the plurality of pixels PX of the active pixel region APR may be processed by the pixel circuit of the first substrate and the logic circuit of the second substrate 210, and may be transmitted to the external element through the bonding pad 390.

Referring to FIG. 3, the transparent planarization layer 350 may be formed not only in the active pixel region APR, but also in the optical black region OB and the connection region CR, which are surrounding regions, and in the pad region PDR. The transparent planarization layer 350 may cover the color filters 340, the light-blocking filter layer 340L, and the first and second connection structures 360 and 370 on the first surface 110a of the first substrate 110, and may provide a flat upper surface. The transparent planarization layer 350 may include a light-transmitting material. In one or more embodiments, the transparent planarization layer 350 may include an organic material such as an acrylic resin, a styrene resin, a polyimide resin, or a siloxane resin.

In one or more embodiments, the meta-optical structure 400 may be provided on the transparent planarization layer 350. As described above, the meta-optical structure 400 may include the plurality of dielectric layers 410, 421 and 422 and the nanoprism patterns NP1 and NP2 disposed in at least one dielectric layer such as dielectric layers 421 or 422. The meta-optical structure 400 in one or more embodiments may include a base dielectric layer 410 and first and second molded layers 421 and 422 having the first and second nanoprism patterns NP1 and NP2, respectively. Refractive indexes, shapes, and heights of the first and second nanoprism patterns NP1 and NP2 may be appropriately designed depending on the wavelength. The nanoprism pattern in one or more embodiments is depicted in the form in which two molded layers 421 and 422 are introduced to obtain a height for securing a desired phase difference to arrange and overlap the first and second nanoprism patterns NP1 and NP2, but embodiments are not limited thereto, and nanoprism patterns having various shapes (e.g., a shape, a height, or the like) may be implemented by introducing one molded layer or three or more molded layers. For example, the first and second molded layers 421 and 422 may include transparent inorganic materials such as silicon oxide, silicon oxynitride, silicon nitride, silicon carbonate, and silicon carbonitride. The base dielectric layer 410 may include a material identical to or similar to the first and second molded layers 421 and 422. The first and second nanoprism patterns NP1 and NP2 may be selected from a material having an appropriate refractive index depending on the wavelength of incident light. For example, the first and second nanoprism patterns NP1 and NP2 may include transparent inorganic materials such as titanium oxide, silicon nitride, niobium oxide, tantalum oxide, aluminum oxide, and hafnium oxide.

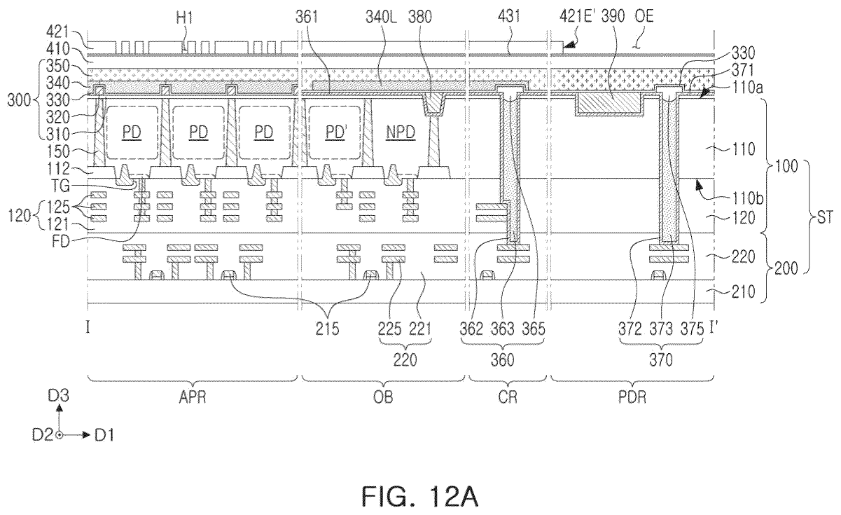

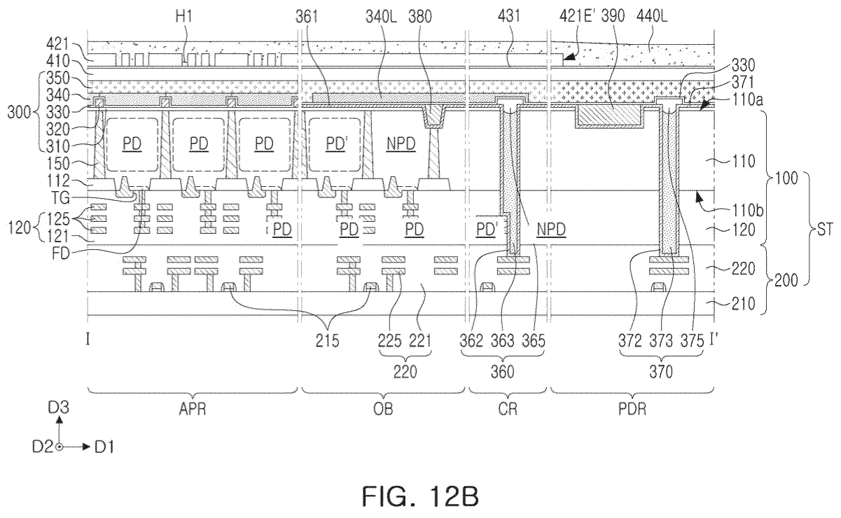

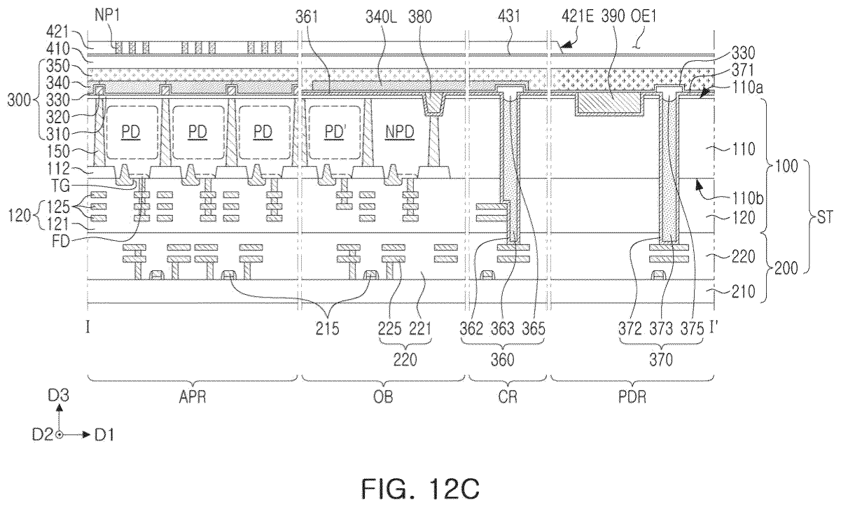

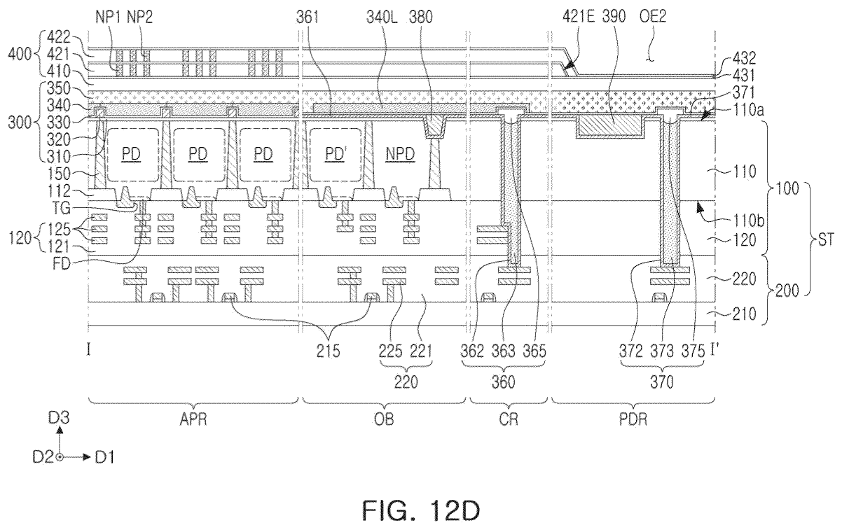

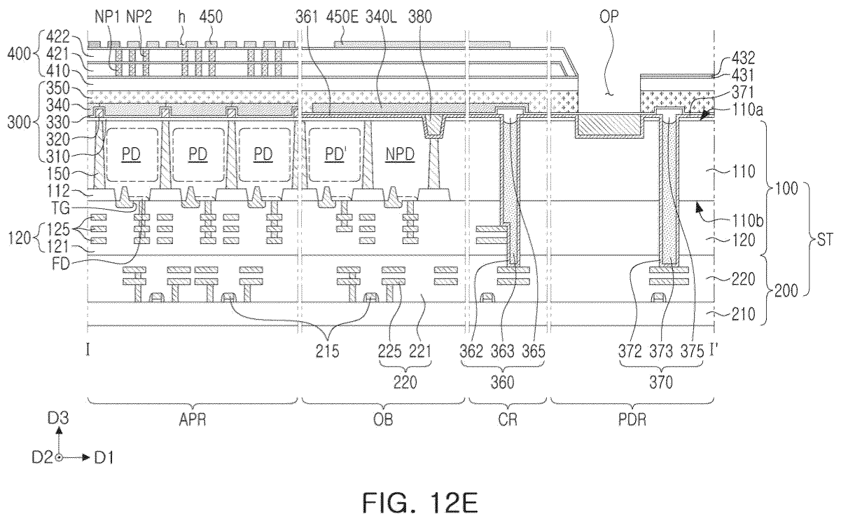

In one or more embodiments, as illustrated in FIG. 3, first and second etch stop layers 431 and 432 may be disposed between the base dielectric layer 410 and the first molded layer 421 and between the first and second molded layers 421 and 422. The first and second etch stop layers 431 and 432 may be used to form holes for the first and second nanoprism patterns NP1 and NP2 in the first and second molded layers 421 and 422, respectively (e.g., see FIG. 12A). The first and second etch stop layers 431 and 432 may include, for example, aluminum oxide.

The meta-optical structure 400 in one or more embodiments may include an anti-reflection layer 450 on the second molded layer 422. The anti-reflection layer 450 may prevent reflection of light incident on the meta-optical structure 400 to increase a light reception rate. The anti-reflection layer 450 may include a material having a different refractive index from the material of the second molded layer 422. For example, the anti-reflection layer 450 may include silicon nitride, aluminum oxide, or hafnium oxide. The anti-reflection layer 450 in one or more embodiments may include a plurality of holes h (see FIG. 2). By introducing the holes h into the anti-reflection layer 450, not only may light interference be prevented, but also light absorbance may be increased to improve the anti-reflection function. In one or more embodiments, a third etch stop layer 433 may be placed between the anti-reflection layer 450 and the second molded layer 422 to form the holes h.

As described above, the first and second nanoprism patterns NP1 and NP2 may be disposed only in the active pixel region APR, but the base dielectric layer 410 and the first and second molded layers 421 and 422 may extend to the peripheral region OB/CR and the pad region PDR.

In one or more embodiments, the pad opening OP opening the bonding pad 390 may be formed by penetrating through a meta-optical structure 400 portion, a transparent planarization layer 350 portion, and a protective film 330 portion, which extend to the pad region PDR. Accordingly, a plurality of interfaces of multiple layers may be exposed on an internal sidewall of the pad opening OP. With the introduction of the meta-optical structure 400, when interfaces of the plurality of dielectric layers 410, 421 and 422 are added, and the transparent planarization layer 350 includes an organic material, an undercut may occur during a dry etching process of forming the pad opening OP, which may lead to reliability problems such as peeling of the meta-optical structure 400.

In one or more embodiments, in order to prevent such problems, a passivation layer PL may be formed on the internal sidewall of the pad opening OP. Since the passivation layer PL covers the exposed interfaces of the meta-optical structure 400 and the exposed side surface of the transparent planarization layer 350, reliability defects due to the formation of the pad opening OP may be effectively prevented.

In one or more embodiments, the passivation layer PL may be formed along with the anti-reflection layer 450 as a portion of the anti-reflection layer 450. The passivation layer PL may include the same material as the anti-reflection layer 450. For example, the passivation layer PL may include silicon nitride, aluminum oxide, or hafnium oxide. In one or more embodiments, since the passivation layer PL is formed on an almost vertical side surface unlike the anti-reflection layer 450 (e.g., the sidewall on which the passivation layer PL is formed may be nearly vertical but slightly inclined at an angle with respect to direction D3), the passivation layer PL may have thicknesses t2a and t2b different from a thickness t1 of the anti-reflection layer of an upper surface of the meta-optical structure 400. For example, the thicknesses t2a and t2b of the passivation layer PL may be less than the thickness t1 of the anti-reflection layer 450.

In one or more embodiments, an anisotropic etching process for forming a hole h in the anti-reflection layer 450 may also be applied to the passivation layer PL. In this process, during the formation of the hole h of the anti-reflection layer 450, an anti-reflection layer portion may be removed from a bottom of the pad opening OP while the passivation layer PL remains on a sidewall of the pad opening OP. In this process, an upper portion of the passivation layer PL may be partially etched, so that the passivation layer PL may have a rounded portion R. For example, a thickness t2b of the upper portion of the passivation layer PL may be less than a thickness t2a of a lower portion of the passivation layer PL. Additionally, the anti-reflection layer 450 may have an expanded portion 450E in the peripheral region (e.g., the optical black region OB and the connection region CR).

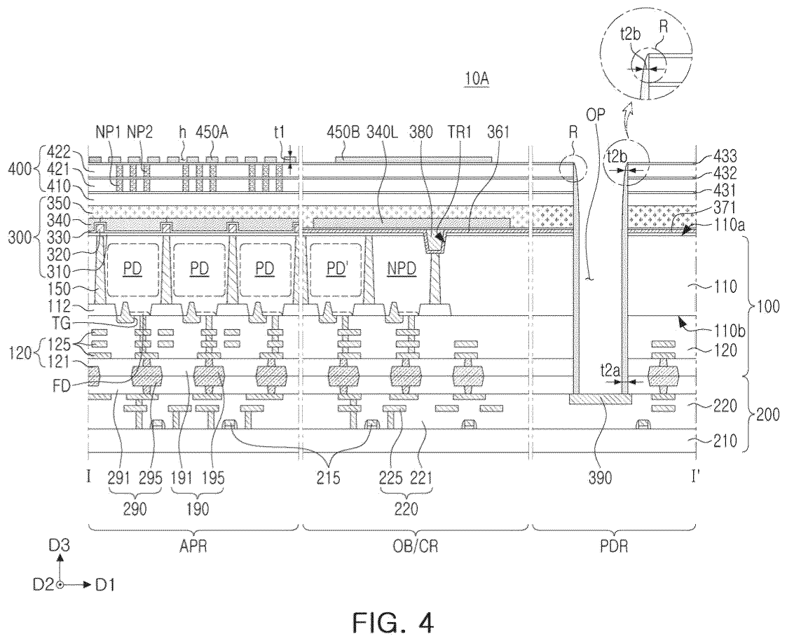

FIG. 4 is a cross-sectional view illustrating an image sensor according to one or more embodiments.

Referring to FIG. 4, an image sensor 10A according to one or more embodiments may be understood as having a structure similar to the image sensor 10 illustrated in FIGS. 1 to 3 (specifically, FIG. 3), except that the bonding pad 390 is disposed on the second substrate structure 200 and the pad opening OP penetrates through the first substrate structure 100, and the first substrate structure 100 and the second substrate structure 200 are connected by a metal-dielectric hybrid bonding instead of the connection structures 360 and 370 (see FIG. 3) as penetration structures. Additionally, the components may be understood by referring to the description of the same or similar components of the image sensor 10 illustrated in FIGS. 1 to 3, and description of aspects that are previously described may be omitted.

In one or more embodiments, the first substrate structure 100 and the second substrate structure 200 may be connected by metal-dielectric hybrid bonding. First and second bonding structures 190 and 290 may be disposed on surfaces on which the first interconnection structure 120 and the second interconnection structure 220 face each other, respectively.

The first bonding structure 190 may include a first bonding insulating layer 191 disposed on the first interconnection structure 120, and first bonding pads 195 electrically connected to the first interconnection structure 120 (e.g., the first interconnection lines 125) in a bonding surface of the first bonding insulating layer 191. The first bonding pads 195 may have a surface that is substantially flat with the bonding surface of the first bonding insulating layer 191. Similarly, the second bonding structure 290 may include a second bonding insulating layer 291 disposed on the second interconnection structure 220, and second bonding pads 295 electrically connected to the second interconnection structure 220 (e.g., the second interconnection lines 225) on the bonding surface of the second bonding insulating layer 291. The second bonding pads 295 may have a surface that is substantially flat with the bonding surface of the second bonding insulating layer 291.

The first and second bonding structures 190 and 290 may be hybrid-bonded through a high-temperature annealing process in a state of bonding the first and second bonding structures 190 and 290. The hybrid bonding may include intermetallic bonding of the first and second bonding pads 195 and 295 and inter-dielectric bonding of the first and second bonding insulating layers 191 and 291. By such hybrid bonding, the first substrate structure 100 and the second substrate structure 200 may be firmly bonded to each other, and the first and second interconnection structures 120 and 220 (e.g., the first interconnection lines 125 and the second interconnection lines 225) may be electrically connected through intermetallic bonding. Accordingly, the first and second bonding pads 195 and 295 may replace a portion or all of the first and second connection structures 360 and 370 used to connect the first and second interconnection structures 120 and 220.

In one or more embodiments, the bonding pad 390 for connection to an external element may be disposed in the second substrate structure 200, and the pad opening OP may be formed to penetrate through the first substrate structure. Referring to FIG. 4, the bonding pad 390 may be disposed on an upper surface of the second interconnection structure 220 and may be connected to the second interconnection structure 220 (e.g., the second interconnection lines 225). The pad opening OP may penetrate not only the first substrate structure 100 but also the first and second bonding structures 190 and 290 so that the bonding pad 390 may be open.

The passivation layer PL may extend to cover a sidewall exposed by the pad opening OP. In one or more embodiments, the passivation layer PL may extend to cover an open internal sidewall of the first substrate structure 100 and open internal sidewalls of the first and second bonding structures 190 and 290.

The passivation layer PL may include the same material as a material of the anti-reflection layer 450. For example, the passivation layer PL may include silicon nitride, aluminum oxide, or hafnium oxide. In one or more embodiments, the passivation layer PL may have thicknesses t2a and t2b, different from the thickness t1 of the anti-reflection layer 450. For example, the thicknesses t2a and t2b of the passivation layer PL may be less than the thickness t1 of the anti-reflection layer 450. In one or more embodiments, for example, the thickness t2b of the upper portion of the passivation layer PL may be less than the thickness t2a of the lower portion of the passivation layer PL. Additionally, the upper portion of the passivation layer PL may have a rounded portion R.

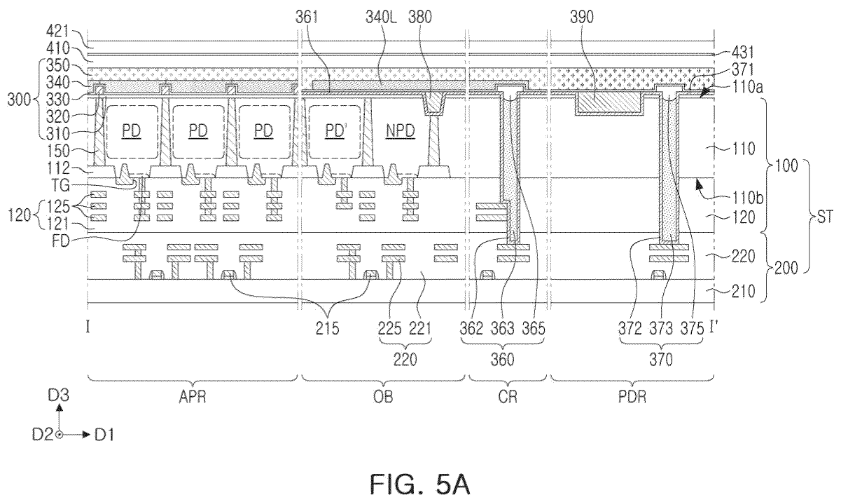

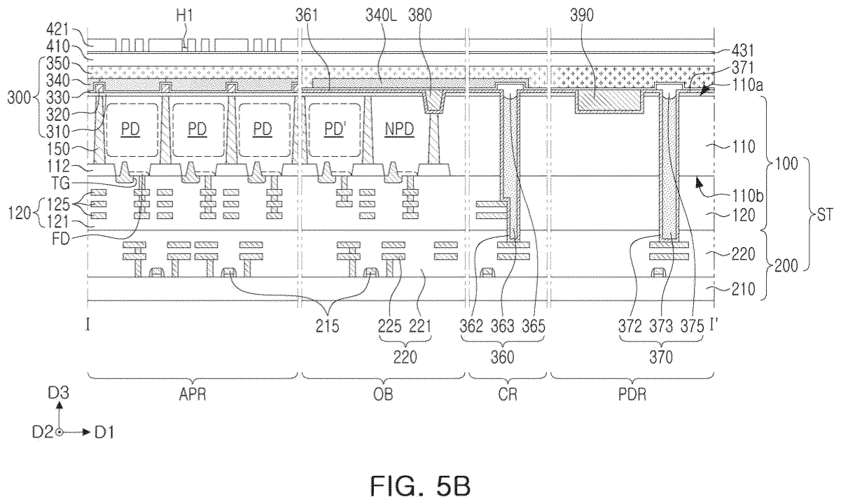

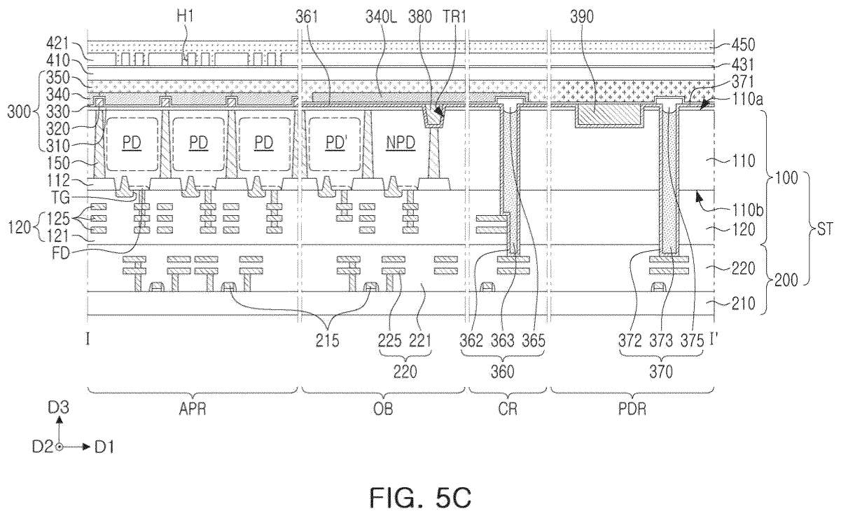

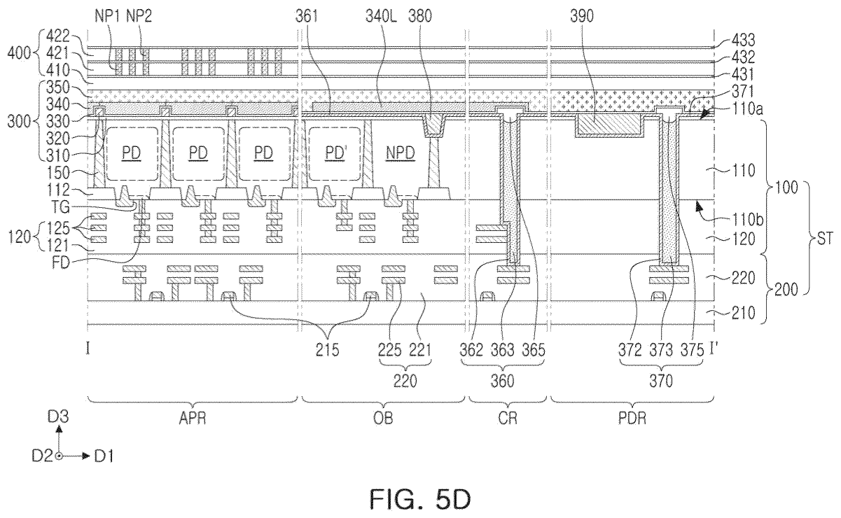

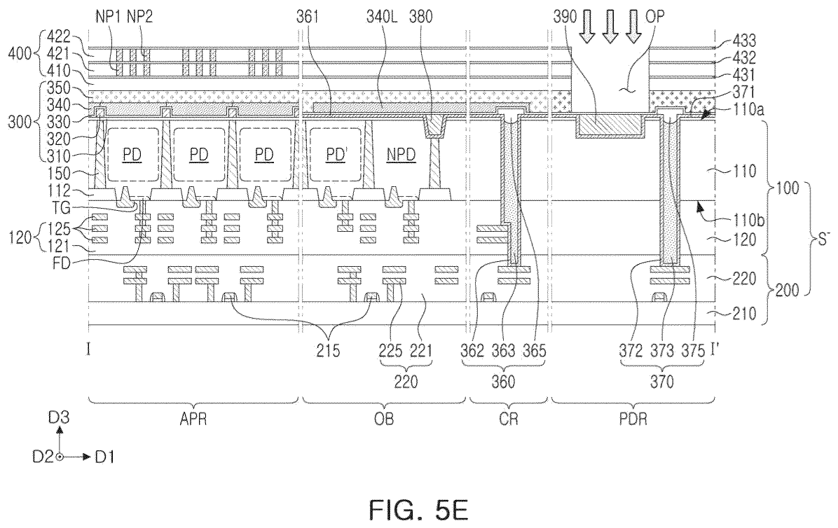

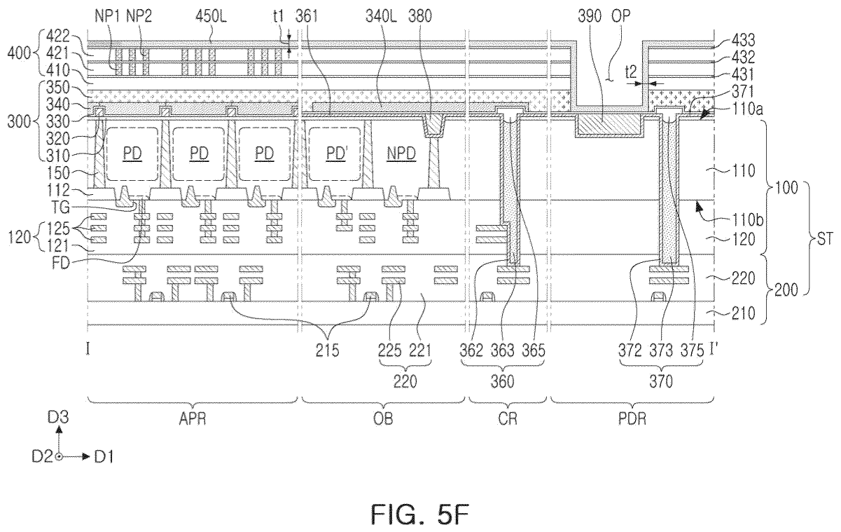

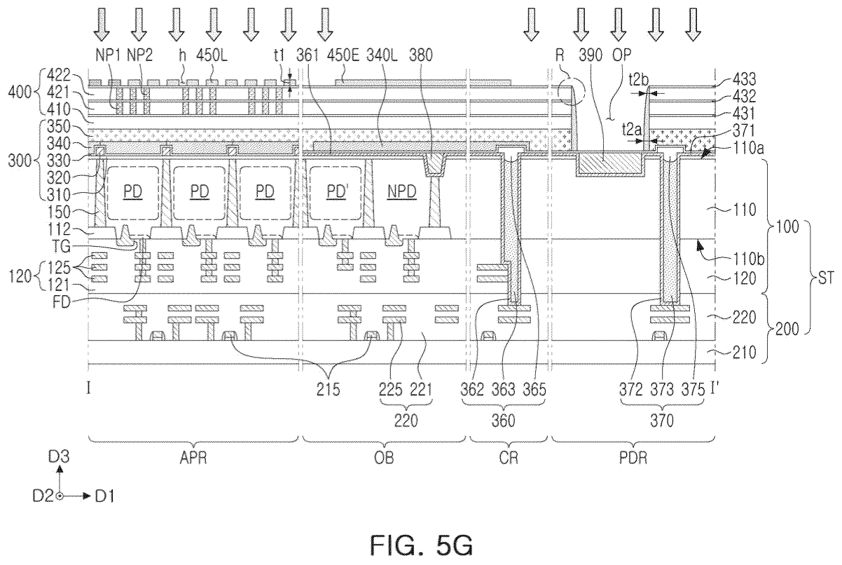

FIGS. 5A to 5G are cross-sectional views illustrating a method of fabricating an image sensor according to one or more embodiments. That is, FIGS. 5A to 5G illustrate a formation process of the meta-optical structure 400 and the formation process of the pad opening OP and the passivation layer PL, in the method for fabricating the image sensor 10 of FIG. 3.

First, in one or more embodiments, after forming a transparent planarization layer 350 at a light incident surface of the image sensor 10, the meta-optical structure 400 may be formed.

Referring to FIG. 5A, a base dielectric layer 410, a first etch stop layer 431, and a first molded layer 421 may be sequentially formed on the transparent planarization layer 350.

For example, the base dielectric layer 410 and the first molded layer 421 may include transparent inorganic materials such as silicon oxide, silicon oxynitride, silicon nitride, silicon carbonate, and silicon carbonitride, and may be formed in a deposition process. For example, the first etch stop layers 431 may include aluminum oxide.

Next, referring to FIG. 5B, the first molded layer 421 may be etched using the first etch stop layer 431 to form hole patterns H1 for a first nanoprism pattern NP1. Next, referring to FIG. 5C, a pattern material layer 440L may be formed on the first molded layer 421 so that the hole patterns H1 are filled, and a planarization process of exposing an upper surface of the first molded layer 421 may be performed, thereby forming the first nanoprism pattern NP1 defined by the hole patterns H1. The pattern material layer 440L included in the first nanoprism pattern NP1 may be selected from materials having an appropriate refractive index depending on the wavelength of the incident light, and for example, the pattern material layer 440L may include a transparent inorganic material such as titanium oxide, silicon nitride, niobium oxide, tantalum oxide, aluminum oxide, and hafnium oxide.

Referring to FIG. 5D, a second molded layer 422 having second nanoprism patterns NP2 may be formed on the first molded layer 421 having the first nanoprism patterns NP1.

The second molded layer 422 having the second nanoprism patterns NP2 may be formed in a process similar to the processes of FIGS. 5B and 5C. Specifically, a second etch stop layer 432 and a second molded layer 422 may be sequentially formed on the first molded layer 421. The second etch stop layer 432 and the second molded layer 422 may use the same material as a material of the first etch stop layer 431 and the first molded layer 421, respectively. Then, similarly to the process of FIG. 5B, hole patterns may be formed in the second molded layer 422, and similarly to the process of FIG. 5C, the hole patterns may be filled with a pattern material layer, and then a chemical mechanical polishing (CMP) process may be performed, thereby forming desired second nanoprism patterns NP2 in the second molded layer 422.

As illustrated in FIG. 5D, a stack body of the meta-optical structure 400 excluding the first and second nanoprism patterns may extend to the peripheral region OB/CR and the pad region PDR. Specifically, the base dielectric layer 410 and the first and second molded layers 421 and 422 may extend to the peripheral region OB/CR and the pad region PDR.

Referring to FIG. 5E, a pad opening OP connected to a bonding pad 390 may be formed in the pad region PDR.

In one or more embodiments, the pad opening OP may be formed to penetrate through stack bodies 410, 421 and 422 of the meta-optical structure 400 and the transparent planarization layer 350. In this process, the protective film 330 covering the bonding pad 390 may not be removed and may remain. The remaining portion of the protective film 330 may protect the bonding pad 390 in a subsequent passivation layer forming process.

Next, referring to FIG. 5F, an anti-reflection material layer 450L may be formed on the upper surface of the meta-optical structure 400 and a surface exposed by the pad opening OP.

The anti-reflection material layer 450L may be relatively conformally deposited not only on the upper surface of the meta-optical structure 400 but also on the surface exposed by the pad opening OP. However, in one or more embodiments, a thickness t2 of the anti-reflection material layer disposed on the internal sidewall of the pad opening OP may be less than the thickness t1 of the anti-reflection material layer disposed on the upper surface of the meta-optical structure 400. For example, the anti-reflection material layer 450L may include silicon nitride, aluminum oxide, or hafnium oxide.

Next, referring to FIG. 5G, a process of patterning the anti-reflection material layer 450L may be performed.

In one or more embodiments, in the anti-reflection material layer 450L, a patterning process may be performed by an anisotropic etching process (e.g., a dry etching process), and may be performed along with a process of forming holes h in the anti-reflection material layer 450L in an active pixel region APR and a process of forming a passivation layer PL in the pad region PDR. In the process of forming the holes h of the anti-reflection layer 450, the anti-reflection material layer may be removed from the bottom of the pad opening OP while the passivation layer PL remains on the sidewall of the pad opening OP. As described above, in this process, the upper portion of the passivation layer PL may be partially etched, so that the passivation layer PL may have a rounded portion R. In one or more embodiments, a portion 450E of the anti-reflection material layer 450L may remain in at least one region of the peripheral region (e.g., the optical black region OB and the connection region CR). Additionally, the bonding pad 390 may be exposed through the pad opening OP by removing the protective film 330 portion exposed to the pad opening OP.

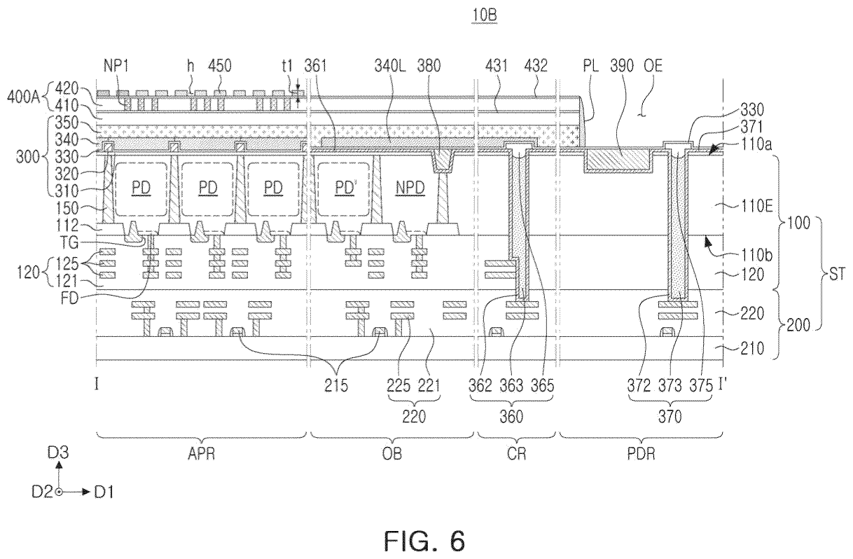

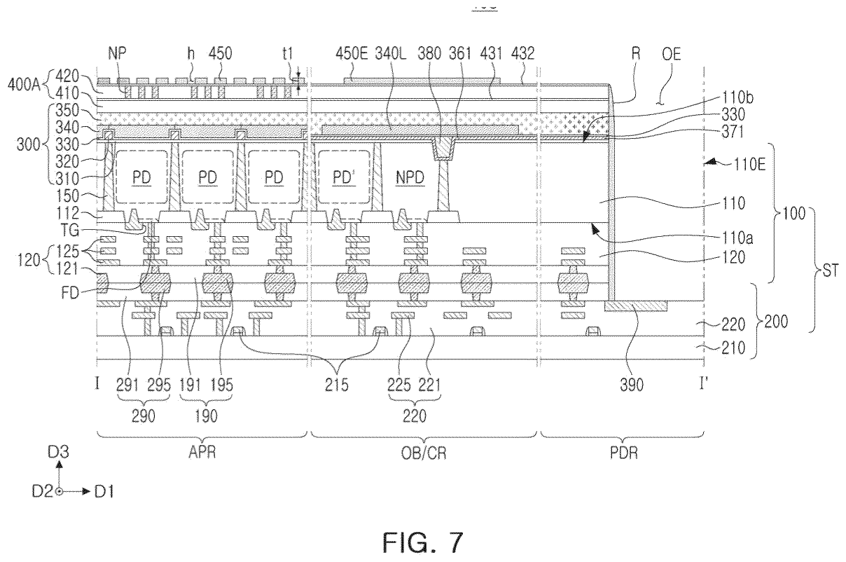

FIGS. 6 and 7 are cross-sectional views illustrating an image sensor according to one or more embodiments.

The pad opening in one or more embodiments may have various shapes. The pad opening (also referred to as an ‘edge-open pad opening’) may be configured to be extend to one edge of the image sensor, as illustrated in FIGS. 6 and 7 and be open on the edge.

First, referring to FIG. 6, an image sensor 10B according to one or more embodiments may be understood as having a structure similar to the image sensor 10 illustrated in FIGS. 1 to 3 (specifically, FIG. 3), except that a pad opening OE extends to one edge 110E of a first surface 110a of the first substrate 110, a material layer for the anti-reflection layer does not remain in the peripheral region, and a meta-optical structure 400A is implemented as a single layer of nanoprism patterns NP. Additionally, the components may be understood by referring to the description of the same or similar components of the image sensor 10 illustrated in FIGS. 1 to 3, and description of aspects that are previously described may be omitted.

In one or more embodiments, the pad opening OE may be extend to one edge 110E of the first surface 110a of the first substrate 110 (see FIG. 2). Since the pad region PDR is disposed on an edge of the image sensor 10B, the pad opening OE may be easily implemented in an open form toward the edge 110E of the first substrate 110. In one or more embodiments, passivation layer PL may be formed along sidewalls of the meta-optical structure 400A and the transparent planarization layer 350 exposed by the pad opening OE.

The passivation layer PL may be formed in the same process as the anti-reflection layer 450, and may include the same material as the anti-reflection layer 450. Additionally, when forming the hole h of the anti-reflection layer 450, a portion for the anti-reflection layer 450 disposed on a bottom portion exposed to the pad opening OE may be removed, and in this process, an upper end of the passivation layer PL may have a rounded portion R. In one or more embodiments, the material layer for the anti-reflection layer 450 disposed in the peripheral region OB/CR may be removed. The removal may be performed along with the formation of the hole h of the anti-reflection layer 450.

The meta-optical structure 400A in one or more embodiments may be implemented as a single layer of nanoprism patterns NP. A refractive index, a shape and a height of the nanoprism pattern NP may be appropriately designed according to the wavelength, and in one or more embodiments, even if a molded layer 420, a single layer, is used, the nanoprism pattern NP may have a height that ensures desired phase difference.

Referring to FIG. 7, am image sensor 10C according to one or more embodiments may be understood as having a structure similar to the image sensor 10 illustrated in FIGS. 1 to 3 (specifically, FIG. 3), except that the bonding pad 390 is disposed on the second substrate structure 200, and the meta-optical structure 400A is implemented as a single layer of nanoprism patterns NP. Additionally, the components may be understood by referring to the description of the same or similar components of the image sensor 10 illustrated in FIGS. 1 to 3, and description of aspects that are previously described may be omitted.

The image sensor 10C according to one or more embodiments may include the bonding pad 390 disposed on the second substrate structure 200. In one or more embodiments, the first substrate structure 100 and the second substrate structure 200 may be bonded by the first and second bonding structures 190 and 290, similarly to the image sensor 10A illustrated in FIG. 4. Such bonding may include intermetallic bonding of the first and second bonding pads 195 and 295 and inter-dielectric bonding of the first and second bonding insulating layers 191 and 291.

The pad opening OE in one or more embodiments may penetrate through not only the first substrate structure 100 but also the first and second bonding structures 190 and 290 so that the bonding pad 390 may be exposed. The pad opening OE may be extend to one edge 110E of the first substrate 110 (e.g., to the edge of the image sensor 10C). In one or more embodiments, not only the sidewalls of the meta-optical structure 400A and the transparent planarization layer 350, but also the sidewalls of the first substrate 110 and the first and second interconnection structures 120 and 220 may be exposed by the pad opening OE. The passivation layer PL may be formed along the exposed sidewalls. The passivation layer PL may include the same material as the anti-reflection layer 450. For example, the passivation layer PL may include silicon nitride, aluminum oxide, or hafnium oxide. Additionally, an upper end of the passivation layer PL may have a rounded portion R.

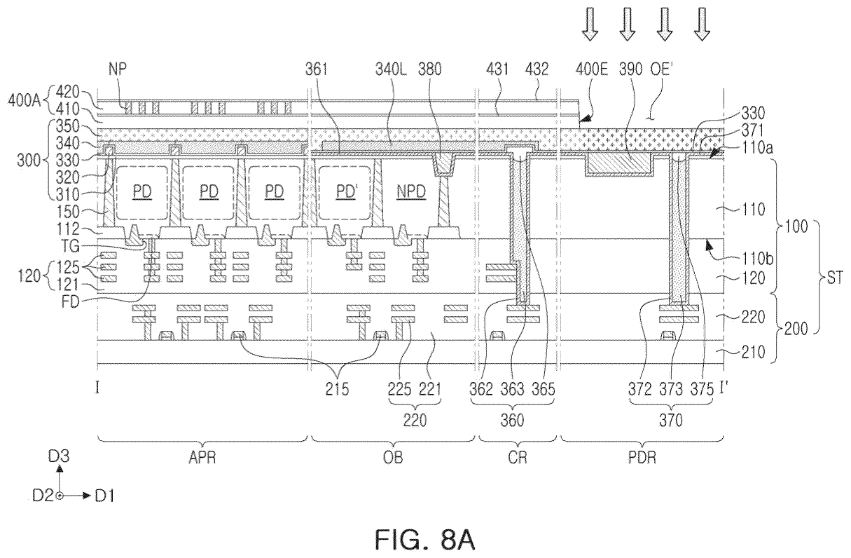

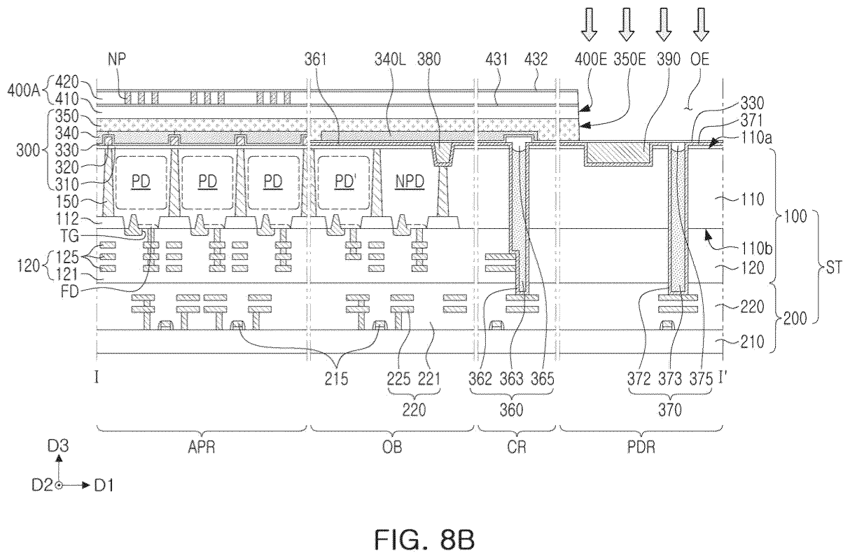

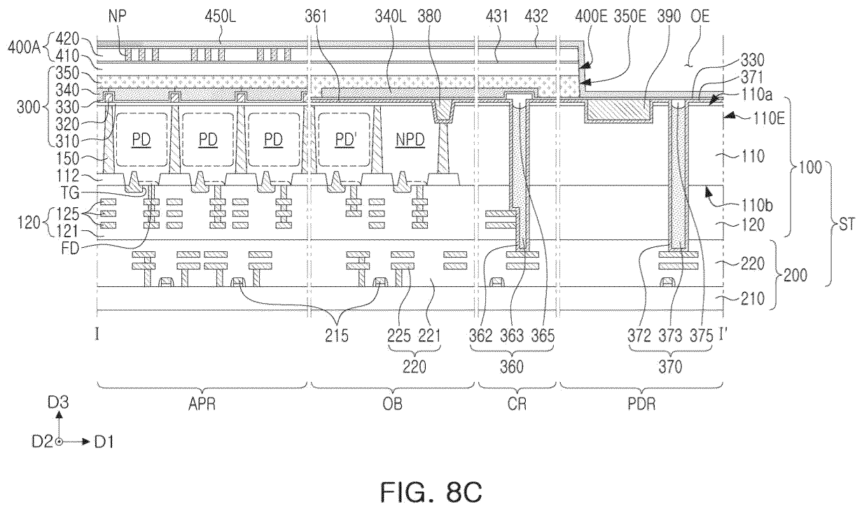

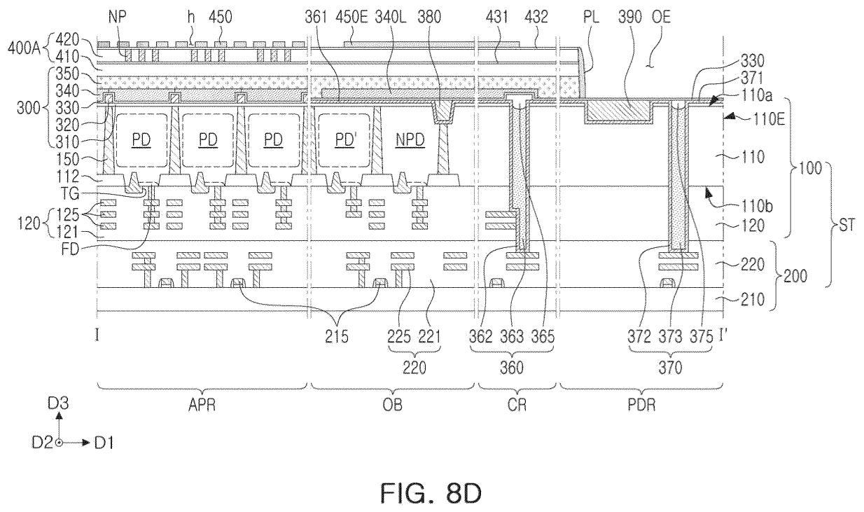

FIGS. 8A to 8D are cross-sectional views illustrating a method of fabricating an image sensor according to one or more embodiments. That is, FIGS. 8A to 8D illustrate a method for fabricating the image sensor 10B of FIG. 6 in a process of forming a pad opening OE and a passivation layer PL.

Referring to FIG. 8A, a meta-optical structure 400A may be formed at light incident surface of the image sensor 10B, that is, on a transparent planarization layer 350, and stack bodies 410, 420, 431 and 432 of the meta-optical structure 400A may be removed to open the bonding pad 390 in the pad region PDR.

In this process, a first opening OE′ for an edge-open pad opening may be formed by removing portions of the stack bodies 410, 420, 431 and 432 of the meta-optical structure 400A from a region in which the bonding pad 390 is disposed, to one edge of the first substrate 110. The stack bodies 410, 420, 431 and 432 may be an inorganic material layer such as silicon oxide or aluminum oxide, and may be removed by a dry etching process.

Referring to FIG. 8B, a portion of the transparent planarization layer 350 exposed to the first opening OE′ may be removed to form an edge-open pad opening OE.

In one or more embodiments, since the transparent planarization layer 350 includes an organic material, the exposed region may be removed by a simple process such as an ashing process. In this manner, the edge-open pad opening OE may be performed by a two-stage removal process such as a dry etching process and an ashing process.

Referring to FIG. 8C, an anti-reflection material layer 450L may be formed on an upper surface of the meta-optical structure 400A and a surface exposed by the pad opening OE. The anti-reflection material layer 450L may be relatively conformally deposited not only on the upper surface of the meta-optical structure 400A but also on the surface exposed by the pad opening OP. Next, referring to FIG. 8D, using an anisotropic etching process (e.g., a dry etching process), holes h may be formed in the anti-reflection material layer 450L in the active pixel region APR, and a passivation layer PL may be formed together therewith in the pad region PDR. In the process of forming the holes h of the anti-reflection layer 450, a portion of the anti-reflection material layer 450L may be removed from a bottom of the pad opening OE while the passivation layer PL remains on a sidewall of the pad opening OE. In one or more embodiments, the anti-reflection material layer 450L may be removed from the peripheral region (e.g., the optical black region OB and the connection region CR). Additionally, the bonding pad 390 may be exposed by removing a portion on the bonding pad 390 in the protective film 330 exposed to the pad opening OE.

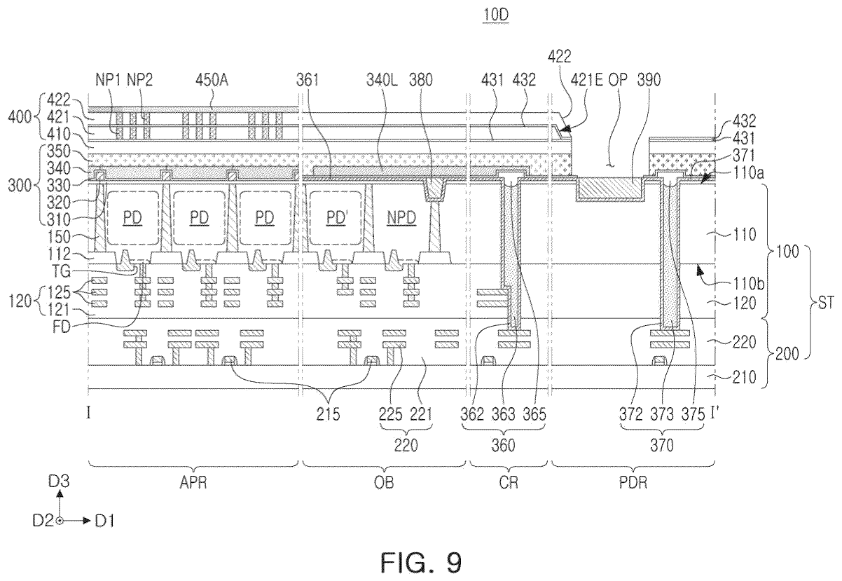

FIGS. 9 to 11 are cross-sectional views illustrating an image sensor according to one or more embodiments. FIGS. 9 to 11 provide a method for reducing an interface between the dielectric layers of the meta-optical structure 400 exposed to a sidewall of the pad opening OP.

Referring to FIG. 9, the image sensor 10D according to one or more embodiments may be understood as having a structure similar to the image sensor 10 illustrated in FIGS. 1 to 3 (specifically, FIG. 3), except that the first molded layer 421 has an edge portion 421E spaced apart from the sidewall of the pad opening OP, the second molded layer 422 covers the edge portion 421E of the first molded layer 421, and an anti-reflection layer 450A is provided only in the active pixel region APR without a hole and the passivation layer is omitted. Additionally, the components may be understood by referring to the description of the same or similar components of the image sensor 10 illustrated in FIGS. 1 to 3, and description of aspects that are previously described may be omitted.

In one or more embodiments, a first molded layer 421 may be disposed on a base dielectric layer 410, and in a pad region PDR, the first molded layer 421 may have the edge portion 421E spaced apart from the sidewall of the pad opening OP. The edge portion 421E of the first molded layer 421 may have a slightly inclined surface by a planarization process such as CMP to obtain a first nanoprism pattern NP1 (see FIG. 12C).

The second molded layer 422 may be disposed on the first molded layer 421, and may cover the edge portion 421E of the first molded layer 421 in the pad region PDR. Accordingly, the second molded layer 422 may extend to the pad opening OP and may be provided as a sidewall of the pad opening OP, while the first molded layer 421 may not be exposed to the sidewall of the pad opening OP. Accordingly, interfaces of the first and second molded layers 421 and 422 may not be exposed onto the sidewall of the pad opening OP. In this manner, according to one or more embodiments, the risk of defects such as delamination due to the interface may be reduced by reducing the interface between the dielectric layers on the sidewall of the pad opening OP.

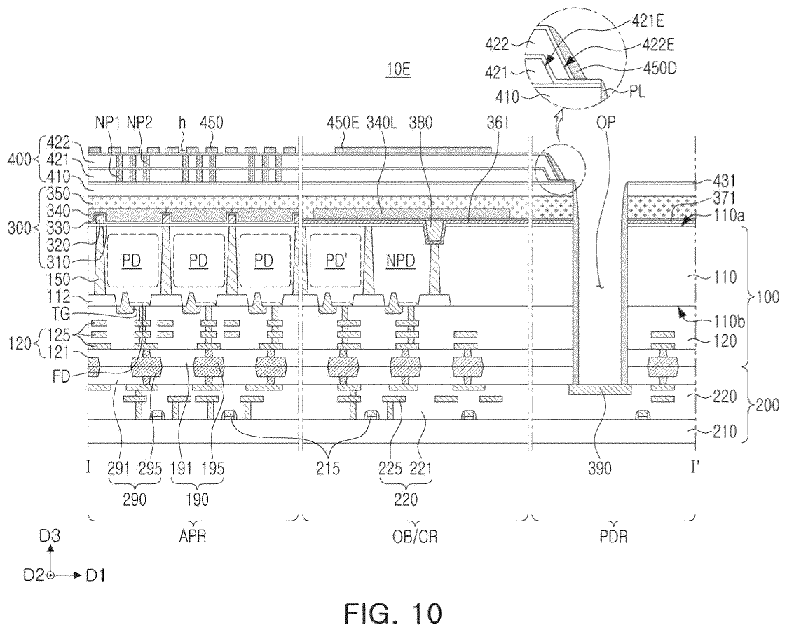

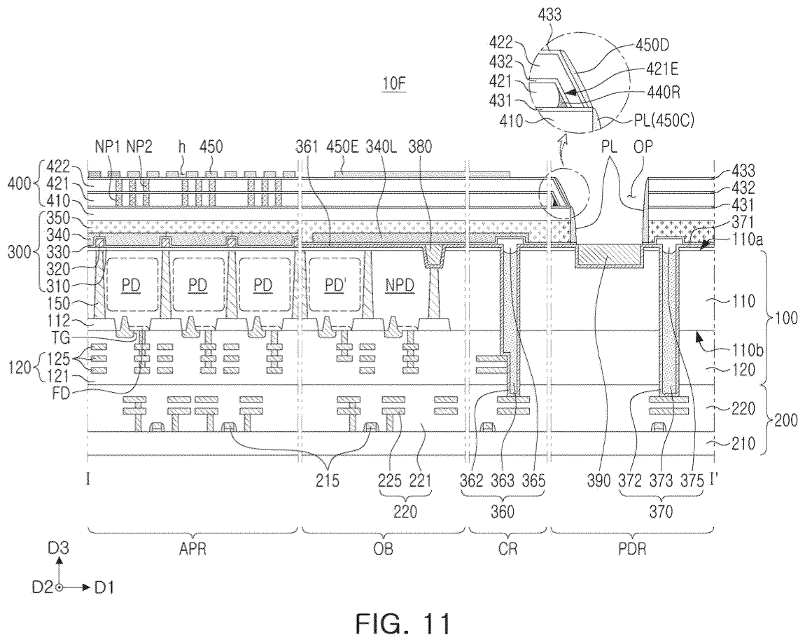

The anti-reflection layer 450A may be implemented in various forms. In one or more embodiments, the anti-reflection layer 450A may be provided only in the active pixel region APR without a hole. In one or more embodiments, the passivation layer may be omitted, but in one or more embodiments, the passivation layer may be implemented to more effectively prevent defects occurring at the pad opening OP (see FIGS. 10 and 11).

Referring to FIG. 10, the image sensor 10E according to one or more embodiments may be understood has a structure similar to the image sensor 10A illustrated in FIG. 4, except that the first molded layer 421 has the edge portion 421E spaced apart from the sidewall of the pad opening OP, and the second molded layer 422 covers the edge portion 421E of the first molded layer 421. Additionally, the components may be understood by referring to the description of the same or similar components of the image sensor 10 illustrated in FIGS. 1 to 3 and the image sensor 10A illustrated in FIG. 4, and description of aspects that are previously described may be omitted.

The image sensor 10E according to one or more embodiments may include a bonding pad 390 disposed on the second substrate structure 200, similarly to the image sensor 10A illustrated in FIG. 4. Additionally, the pad opening OP may penetrate through portions of the first substrate structure 100 and the second interconnection structure 220 so that the bonding pad 390 may be open.

The first and second substrate structures 100 and 200 in one or more embodiments may be bonded by the first and second bonding structures 190 and 290, similarly to the image sensor 10A illustrated in FIG. 4. Such bonding may include intermetallic bonding of the first and second bonding pads 195 and 295 and inter-dielectric bonding of the first and second bonding insulating layers 191 and 291.

The first molded layer 421 may have the edge portion 421E spaced apart from the sidewall of the pad opening OP on the base dielectric layer 410. The second molded layer 422 may cover the edge portion 421E of the first molded layer 421 on the first molded layer 421. Accordingly, an interface between the first and second molded layers 421 and 422 may not be exposed on the sidewall of the pad opening OP. In this manner, in one or more embodiments, the risk of defects such as delamination due to the interface may be reduced by reducing the interface between the dielectric layers on the sidewall of the pad opening OP.

The image sensor 10E according to one or more embodiments may include the passivation layer PL disposed on the sidewall of the pad opening OP. Other interfaces of the meta-optical structure 400 and the sidewall of the transparent planarization layer 350 may be protected by the passivation layer PL. This passivation layer PL may be formed using a formation process of the anti-reflection layer 450, specifically, the formation process of the hole h, similarly to the passivation layer PL described in FIG. 4.

A material layer 450D similar to the passivation layer PL may also remain on the sidewall of the meta-optical structure 400 in one or more embodiments. Similarly to the edge portion 421E of the first molded layer 421, an edge portion 422E of the second molded layer 422 may also have an inclined sidewall in a planarization process such as CMP, so that the material layer 450D disposed on the sidewall of the meta-optical structure 400 may remain to have a thickness thinner than a thickness of the passivation layer PL.

Referring to FIG. 11, the image sensor 10F according to one or more embodiments may be understood as having a structure similar to the image sensor 10D illustrated in FIG. 9, except that a pattern material 440R remains in the edge portion 421E of the first molded layer 421, an edge portion of the meta-optical structure 400 is adjacent to the pad opening OP, a hole h is formed in an anti-reflection layer 500, and a passivation layer PL is formed in the pad opening OP. Additionally, the components may be understood by referring to the description of the same or similar components of the image sensor 10 illustrated in FIGS. 1 to 3 and the image sensor 10D illustrated in FIG. 9, and description of aspects that are previously described may be omitted.

The pattern material 440R may remain in the edge portion 421E of the first molded layer 421. The remaining pattern material 440R may be obtained by allowing a portion of a pattern material layer 440L (see FIG. 12B) deposited on an almost vertical edge portion 421E′ of the first molded layer 421 to remain in an inclined edge portion 421E of the first molded layer 421 even after a CMP process. Accordingly, the remaining pattern material 440R may include the same material as the first nanoprism pattern NP1.

A position of the edge portion of the meta-optical structure 400 may be variously changed. In one or more embodiments, the edge portion of the meta-optical structure 400 may be disposed adjacently to the pad opening OP. The position of the edge portion of the meta-optical structure 400 may be determined by a position of the edge portion 421E of the first molded layer 421. The position of the edge portion 421E of the first molded layer 421 may be disposed in the pad region PDR, but in one or more embodiments, the position of the edge portion 421E may be disposed in the connection region CR.

The image sensor 10F according to one or more embodiments may include a passivation layer PL disposed on the sidewall of the pad opening OP. The other interfaces of the meta-optical structure 400 and the sidewall of the transparent planarization layer 350 may be protected by the passivation layer PL. The passivation layer PL may be formed using the formation process of the anti-reflection layer 450, specifically, the formation process of the hole h, similarly to the passivation layer PL described in FIG. 4. A material layer 450D similar to the passivation layer PL may remain on an inclined sidewall of the meta-optical structure 400 in one or more embodiments. The material layer 450D disposed on the inclined sidewall of the meta-optical structure 400 may remain to have a thickness thinner than the thickness of the passivation layer PL.

In this manner, in the formation process of the meta-optical structure 400, the lower dielectric layer may be spaced apart from the pad opening OP and an upper dielectric layer may be formed to cover a spaced portion of the lower dielectric layer, thereby reducing an interface of the dielectric layer exposed from the sidewall of the pad opening OP.

FIGS. 12A to 12E are cross-sectional views illustrating a method of fabricating an image sensor according to one or more embodiments. That is, FIGS. 12A to 12E illustrate a process of manufacturing the image sensor 10D.

Referring to FIG. 12A, the first molded layer 421 may be etched using the first etch stop layer 431 to form hole patterns H1 for the first nanoprism pattern NP1. In an etching process for the hole pattern H1, the first molded layer 421 may be partially removed in the pad region PDR so that a first opening OE1 may be formed to be exposed toward one edge of the first substrate 110. The first opening OE1 may be formed so that the edge portion 421E′ of the first molded layer 421 may be sufficiently spaced apart from a region vertically overlapping the bonding pad 390. The edge portion 421E′ obtained in this process may have an almost vertical side surface, similarly to the hole pattern H1.

Next, referring to FIG. 12B, a pattern material layer 440L may be formed on the first molded layer 421 so that the hole patterns H1 may be filled. The pattern material layer 440L may also be formed to be filled in the first opening OE1 disposed in the pad region PDR. For example, the pattern material layer 440L may include a transparent inorganic material such as titanium oxide, silicon nitride, niobium oxide, tantalum oxide, aluminum oxide, and hafnium oxide.

Referring to FIG. 12C, a first nanoprism pattern NP1 defined by hole patterns H1 may be formed by performing a planarization process such as CMP. In the process of removing a portion of the pattern material layer 440L on the first molded layer 421, a portion of the pattern material layer 440L in the first opening OE1 may also be removed together. Even though the portion of the pattern material layer 440L in the first opening OE1 is disposed at a somewhat lower level (i.e., on a base dielectric layer), the portion of the pattern material layer 440L may be adjacent to the edge, so that the portion of the pattern material layer 440L may be removed together with the pattern material layer 440L on the first molded layer 421 in the CMP process. In one or more embodiments, a pattern material layer (see ‘440R’ of FIG. 11) may partially remain on the edge of the first molded layer 421 after the CMP process.

Next, referring to FIG. 12D, a second molded layer 422 having second nanoprism patterns NP2 may be formed on the first molded layer 421 having first nanoprism patterns NP1.

In this process, a second opening OE2 may be formed in the second molded layer 422 disposed on the base dielectric layer 410 in the pad region PDR. Similarly to the first opening OE1, the second opening OE2 may also be formed together in the process of forming the hole pattern for the second nanoprism pattern NP2 in the second molded layer 422. The second opening OE2 may also have a structure exposed toward the edge, similarly to the first opening OE1, while including a region overlapping the bonding pad 390.

Next, referring to FIG. 12E, an anti-reflection layer 450A may be formed in the active pixel region APR, and a pad opening OP connected to the bonding pad 390 may be formed in the pad region PDR.

In one or more embodiments, the process of forming the anti-reflection layer 450A may be formed before forming the pad opening OP.

In one or more embodiments, the pad opening OP may be formed in the second opening OE2, and may be formed to penetrate through the base dielectric layer 410 of the meta-optical structure 400 and the transparent planarization layer 350. The remaining protective film 330 may protect the bonding pad 390 in a subsequent passivation layer forming process. A process of patterning the anti-reflection material layer 450L may be performed. Additionally, the bonding pad 390 may be exposed through the pad opening OP by removing a portion of the protective film 330 exposed to the pad opening OP.

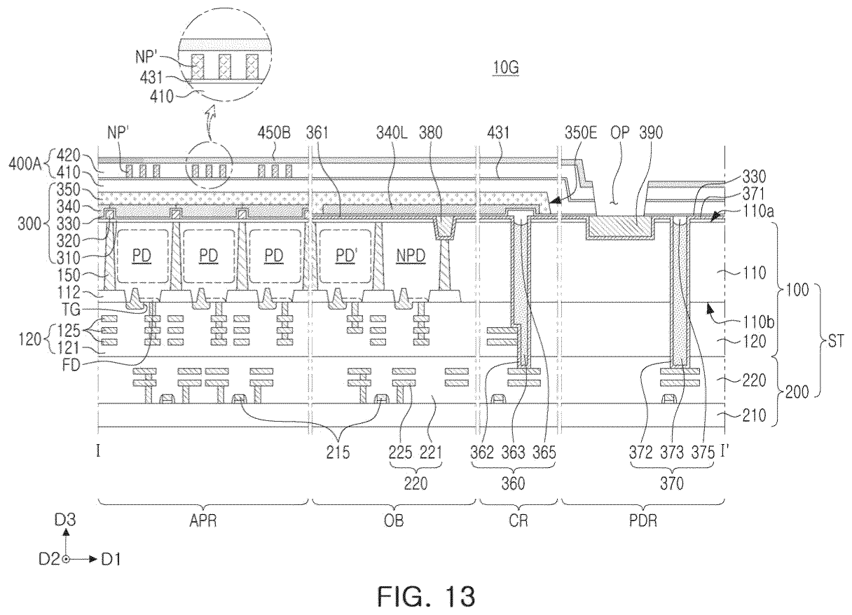

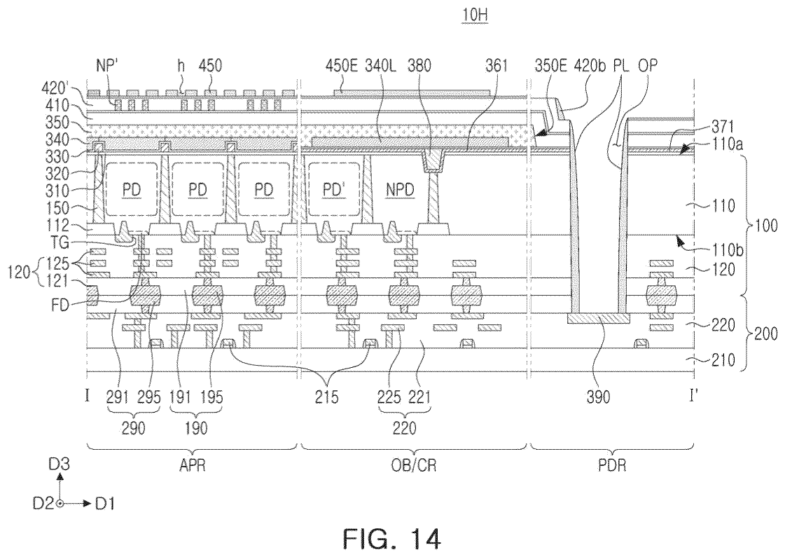

FIGS. 13 and 14 are cross-sectional views illustrating an image sensor according to one or more embodiments. FIGS. 13 and 14 provide a method of preventing exposure of the transparent planarization layer 350 to the sidewall of the pad opening OP without a passivation layer.

Referring to FIG. 13, the image sensor 10G according to one or more embodiments may be understood as having a structure similar to the image sensor 10 shown in FIGS. 1 to 3 (specifically, FIG. 3), except that the transparent planarization layer 350 has an edge portion 350E spaced apart from the pad opening OP, a meta-optical structure 400B covers the edge portion 350E of the transparent planarization layer 350, the meta-optical structure 400B has a new structure, and an anti-reflection layer 450B is provided on an upper surface of the meta-optical structure 400B and the passivation layer is omitted. Additionally, the components may be understood by referring to the description of the same or similar components of the image sensor 10 illustrated in FIGS. 1 to 3, and description of aspects that are previously described may be omitted.

The transparent planarization layer 350 may cover the color filters 340, the light-blocking filter layer 340L, and the first connection structures 360 on the first surface 110a of the first substrate 110, and may provide a flat upper surface. The transparent planarization layer 350 may be formed only in the active pixel region APR, the optical black region OB, and the connection region CR. In one or more embodiments, the transparent planarization layer 350 may extend by a portion of the pad region PDR.

In one or more embodiments, the transparent planarization layer 350 has an edge portion 350E spaced apart from the pad opening OP, and the meta-optical structure 400B may cover the edge portion 350E of the transparent planarization layer 350. In one or more embodiments, the transparent planarization layer 350 may include an organic material such as an acrylic resin, a styrene resin, a polyimide resin, or a siloxane resin. In this manner, the transparent planarization layer 350 may include an organic material, and in this case, an undercut may occur during the formation of the pad opening OP, but in one or more embodiments, since the edge portion 350E of the transparent planarization layer 350 is covered with the base dielectric layer 410 and the molded layer 420,′ the exposure of the transparent planarization layer 350 in the sidewall of the pad opening OP may be prevented.

The meta-optical structure 400B may include a base dielectric layer 410, nanoprism patterns NP′ on the base dielectric layer 410, and a molded layer 420′ disposed on the base dielectric layer 410 and covering the nanoprism patterns NP.′ In one or more embodiments, an etch stop layer 431 and a pattern material layer may be sequentially formed on the base dielectric layer 410, and the pattern material layer may be etched using the etch stop layer 431 to form nanoprism patterns NP.′ Then, the molded layer 420′ may be formed to cover the nanoprism patterns NP′, thereby forming the meta-optical structure 400B in one or more embodiments.

The anti-reflection layer 450B may be formed up to the active pixel region APR, the peripheral region OB/CR, and the pad region PDR without a hole. The pad opening OP may be formed to penetrate through the anti-reflection layer 450B and the meta-optical structure 400B. In one or more embodiments, the passivation layer is omitted, but in one or more embodiments, the passivation layer may be combined with a method of reducing the interface between dielectric layers to more effectively prevent defects occurring in the pad opening OP (see FIG. 14).

Referring to FIG. 14, the image sensor 10H according to one or more embodiments may be understood as having a structure similar to the image sensor 10A illustrated in FIG. 4, except that the transparent planarization layer 350 has an edge portion 350E spaced apart from the sidewall of the pad opening OP, the meta-optical structure 400B covers the edge portion 350E of the transparent planarization layer 350, and the meta-optical structure 400B has a new structure. Additionally, the components may be understood by referring to the description of the same or similar components of the image sensor 10 illustrated in FIGS. 1 to 3 and the image sensor 10A illustrated in FIG. 4, and description of aspects that are previously described may be omitted.

The image sensor 10E according to one or more embodiments may include a bonding pad 390 disposed on the second substrate structure 200, similarly to the image sensor 10A illustrated in FIG. 4. Additionally, the pad opening OP may penetrate through portions of the first substrate structure 100 and the second interconnection structure 220 so that the bonding pad 390 may be open.

The first and second substrate structures 100 and 200 in one or more embodiments may be bonded by the first and second bonding structures 190 and 290 similarly to the image sensor 10A illustrated in FIG. 4. Such bonding may include intermetallic bonding of the first and second bonding pads 195 and 295 and inter-dielectric bonding of the first and second bonding insulating layers 191 and 291.

In one or more embodiments, the transparent planarization layer 350 may cover the color filters 340, the light-blocking filter layer 340L, and the first connection structures 360 on the first surface 110a of the first substrate 110 and may provide a flat upper surface. The transparent planarization layer 350 may have an edge portion 350E spaced apart from the pad opening OP, and the meta-optical structure 400B may cover the edge portion 350E of the transparent planarization layer 350. In this manner, the edge portion 350E of the transparent planarization layer 350, which may be an organic material, may be covered with the base dielectric layer 410 and the molded layer 420′, thereby preventing exposure of the transparent planarization layer 350 in the sidewall of the pad opening OP.

The meta-optical structure 400B in one or more embodiments may include a base dielectric layer 410, nanoprism patterns NP′ on the base dielectric layer 410, and a molded layer 420′ disposed on the base dielectric layer 410 and covering the nanoprism patterns NP′.

The image sensor 10H according to one or more embodiments may include a passivation layer PL disposed on a sidewall of the pad opening OP. Other interfaces of the meta-optical structure 400 and the side surface of the transparent planarization layer 350 may be protected by the passivation layer PL. Similarly to the passivation layer PL described in FIG. 4, the passivation layer PL may be formed using a process for forming the anti-reflection layer 450, specifically, a process for forming holes h.

A material layer 450D similar to the passivation layer PL may also remain on the sidewall of the meta-optical structure 400B in one or more embodiments. Similarly to the edge portion 421E of the first molded layer 421, the edge portion 422E of the second molded layer 422 may also have an inclined sidewall in a planarization process such as a CMP process, and thus, the material layer 450D disposed on the sidewall of the meta-optical structure 400 may remain to have a thickness thinner than the thickness of the passivation layer PL.

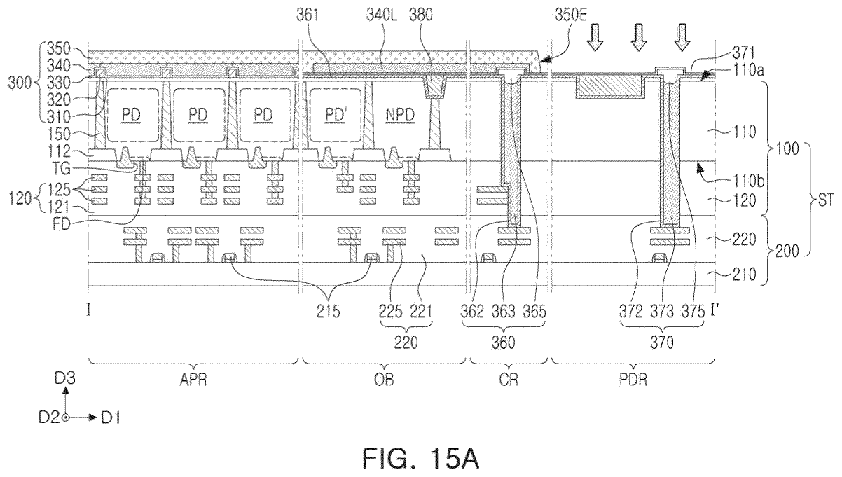

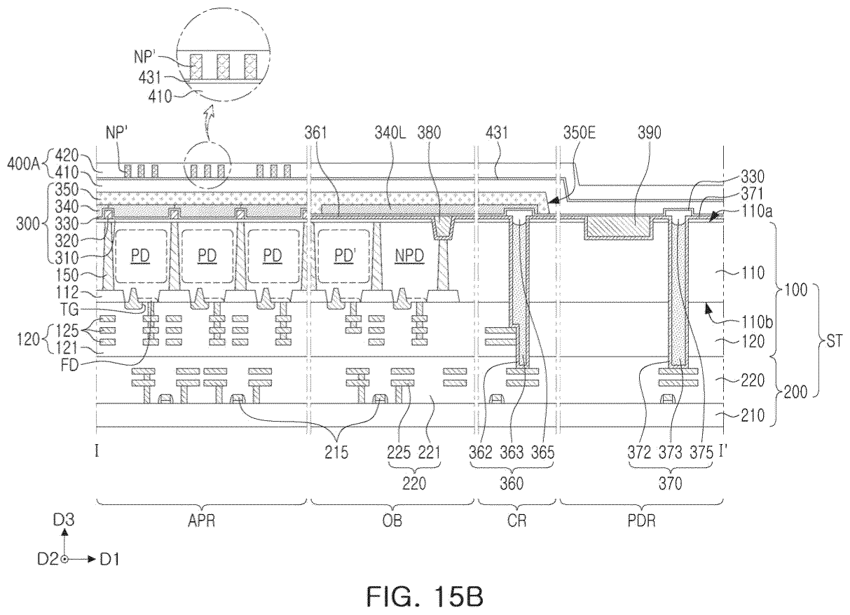

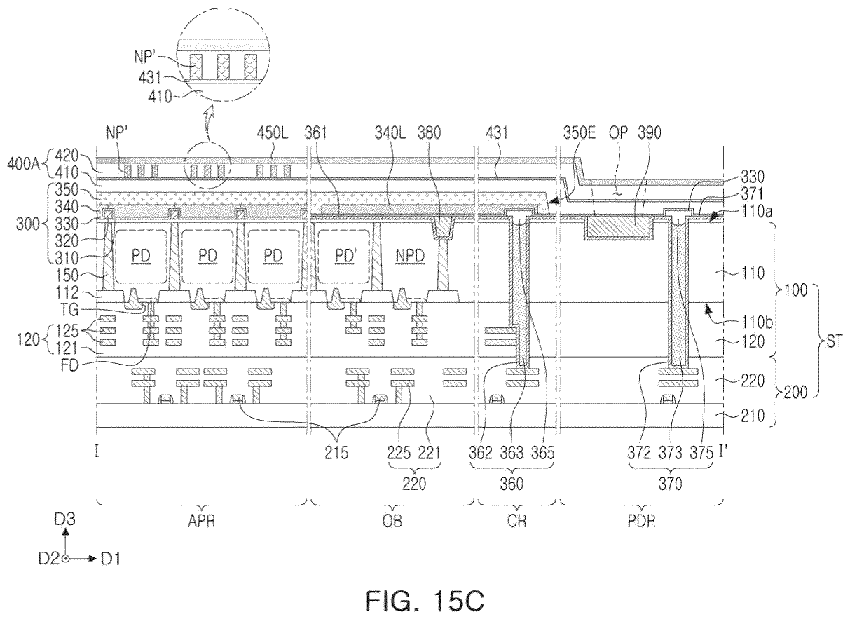

FIGS. 15A to 15C are cross-sectional side views illustrating a method of fabricating an image sensor according to one or more embodiments. That is, FIGS. 15A to 15F show a method for fabricating the image sensor 10G of FIG. 13.

Referring to FIG. 15A, a transparent planarization layer 350 having an edge portion 350E spaced apart from a pad opening OP may be formed on a first surface 110a of a first substrate 110.

First, a transparent planarization layer 350 may be formed on the first surface 110a of the first substrate 110 to cover the color filters 340, the light-blocking filter layer 340L, and the first and second connection structures 360 and 370. The transparent planarization layer 350 may be formed over the active pixel region APR, the optical black region OB, the connection region CR, and the pad region PDR, and may have a flat upper surface. Then, a first opening OE1′ may be formed to open toward one edge of the first substrate 110 by partially removing the transparent planarization layer 350 in the pad region PDR.

Referring to FIG. 15B, a base dielectric layer 410 may be formed, and nanoprism patterns NP′ may be formed on the base dielectric layer 410. In this process, an etch stop layer 431 and a pattern material layer may be sequentially formed on the base dielectric layer 410, and the pattern material layer may be etched using the etch stop layer 431 to form nanoprism patterns NP′.

Referring to FIG. 15C, a molded layer 420′ may be formed to cover the nanoprism patterns NP′ to form the meta-optical structure 400B, and additionally, an anti-reflection layer 450B may be formed on the meta-optical structure 400B. The anti-reflection layer 450B may be formed up to the active pixel region APR, the peripheral region OB/CR, and the pad region PDR without a hole. Then, a pad opening OP may be formed to penetrate through the anti-reflection layer 450B and the meta-optical structure 400B.

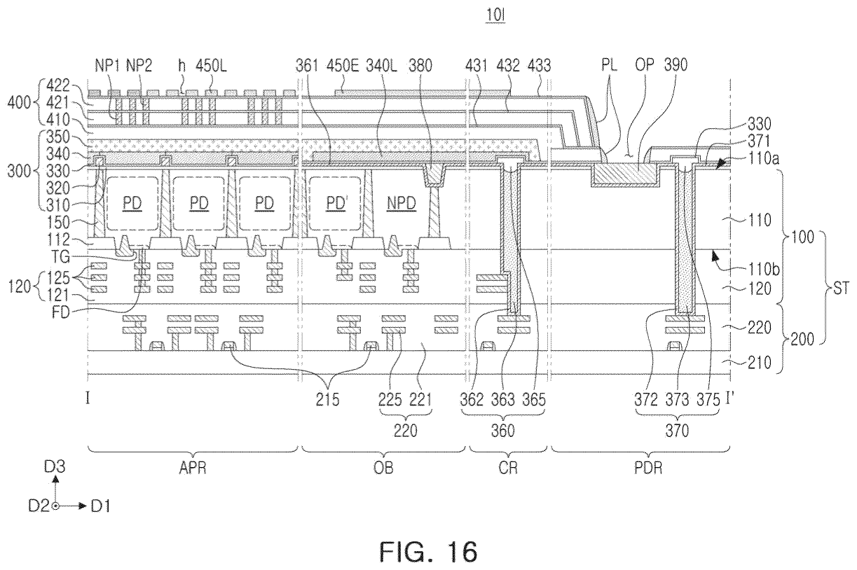

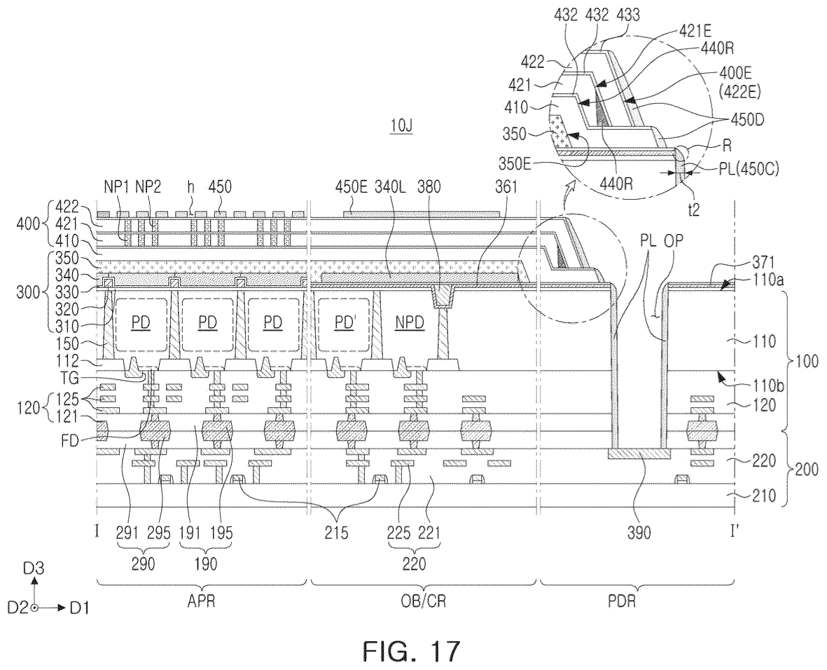

FIGS. 16 and 17 are cross-sectional views illustrating an image sensor according to one or more embodiments.

An image sensor according to one or more embodiments in which the above-described unique components are combined are exemplified in FIGS. 16 and 17.

Referring to FIG. 16, an image sensor 10I according to one or more embodiments may include a configuration for introducing a passive layer PL to the sidewall of the pad opening OP (see FIG. 3), a configuration for preventing the exposure of the transparent planarization layer 350 to the sidewall of the pad opening OP (see FIG. 13), and a configuration for preventing the exposure of an interface between the first and second molded layers 421 and 422 of the meta-optical structure 400 exposed to the sidewall of the pad opening OP (see FIG. 9 and FIG. 11), and, components may be understood by referring to the descriptions of the same or similar components of the image sensors 10 illustrated in FIGS. 1 to 3, and the image sensors 10D, 10F and 10G illustrated in FIGS. 9, 11, and 13, and description of aspects that are previously described may be omitted.

The transparent planarization layer 350 in one or more embodiments may have an edge portion 350E spaced apart from the pad opening OP, and the meta-optical structure 400 may cover the edge portion 350E of the transparent planarization layer 350. Since the edge portion 350E of the transparent planarization layer 350, which is susceptible to damage, is covered with the base dielectric layer 410 and the first and second molded layers 421 and 422, exposure of the transparent planarization layer 350 at the sidewall of the pad opening OP may be prevented.

Additionally, the meta-optical structure 400 in one or more embodiments may include a first molded layer 421 having an edge portion 421E spaced apart from the sidewall of the pad opening OP on the base dielectric layer 410, and a second molded layer 422 disposed on the first molded layer and covering the edge portion 421E of the first molded layer 421.

The edge portion 421E of the first molded layer 421 may have a slightly inclined surface by a planarization process such as a CMP process to obtain the first nanoprism pattern NP1. In one or more embodiments, the second molded layer may cover the edge portion 421E of the first molded layer 421 and may extend on the base dielectric layer region adjacent to the pad opening. In this manner, interfaces of the first molded layer 421 and the second molded layer 422 may not be exposed to the sidewall of the pad opening OP.

The image sensor 10I according to one or more embodiments may include a passivation layer PL disposed on the sidewall of the pad opening OP. An edge portion of the meta-optical structure 400 and a side surface of the base dielectric layer 410 may be protected by the passivation layer PL. This passivation layer PL may be formed using a formation process of the anti-reflection layer 450, specifically, a process of forming holes h, similarly to the passivation layer PL described in FIG. 3.

Referring to FIG. 17, an image sensor 10J according to one or more embodiments may be understood as having a structure similar to the image sensor 10I illustrated in FIG. 16, except that the bonding pad 390 is disposed on the second substrate structure 200 and the pad opening OP penetrates through the first substrate structure 100, the first substrate structure 100 and the second substrate structure 200 are connected by a metal-to-dielectric hybrid bonding instead of the connection structures 360 and 370 (see FIG. 16), which are penetration structures, and the pattern material 440R remains on the edge portion 421E of the first molded layer 421.

The image sensor 10J according to one or more embodiments may include a configuration for introducing the passive layer PL to the sidewall of the pad opening OP (see FIG. 4), a configuration for preventing the exposure of the transparent planarization layer 350 to the sidewall of the pad opening OP (see FIG. 14), and a configuration for preventing the exposure of the interface between the first and second molded layers 421 and 422 of the meta-optical structure 400 exposed on the sidewall of the pad opening OP (see FIG. 10), and the components may be understood by referring to the description of the same or similar components of the image sensors 10A, 10E and 10H illustrated in FIG. 4, FIG. 10 and FIG. 14, along with the image sensor 10I illustrated in FIG. 16, and description of aspects that are previously described may be omitted.

The image sensor 10J according to one or more embodiments may include a bonding pad 390 disposed on a second substrate structure 200, and the pad opening OP penetrates through portions of the first substrate structure 100 and the second interconnection structure 220 so that the bonding pad 390 may be open. The first and second substrate structures 100 and 200 in one or more embodiments may be bonded by the first and second bonding structures 190 and 290 similarly to the image sensor 10A illustrated in FIG. 4. Such bonding may include intermetallic bonding of the first and second bonding pads 195 and 295 and inter-dielectric bonding of the first and second bonding insulating layers 191 and 291.

The transparent planarization layer 350 in one or more embodiments may have an edge portion 350E spaced apart from the pad opening OP, and the meta-optical structure 400 may cover the edge portion 350E of the transparent planarization layer 350. This may prevent the exposure of the transparent planarization layer 350 in the sidewall of the pad opening OP.

The meta-optical structure 400 in one or more embodiments may include a first molded layer 421 having an edge portion 421E spaced apart from the sidewall of the pad opening OP on the base dielectric layer 410, and a second molded layer 422 disposed on the first molded layer and covering the edge portion 421E of the first molded layer 421. Accordingly, the interface between the first molded layer 421 and the second molded layer 422 may not be exposed to the sidewall of the pad opening OP.

The image sensor 10J according to one or more embodiments may include a passivation layer PL disposed on the sidewall of the pad opening OP. An edge portion of the meta-optical structure 400 and a side surface of the base dielectric layer 410 may be protected by the passivation layer PL.

The passivation layer PL may be formed using the process for forming the anti-reflection layer 450, specifically, the process of forming holes h. A material layer 450D similar to the passivation layer PL may also remain on the sidewall of the meta-optical structure 400 in one or more embodiments. Similarly to the edge portion 421E of the first molded layer 421, since the edge portion 422E of the second molded layer 422 also has an inclined sidewall in the planarization process such as a CMP process, the material layer 450D disposed on the sidewall of the meta-optical structure 400 may remain to have a thickness thinner than the thickness of the passivation layer PL.

In one or more embodiments, a remaining pattern material 440R may be disposed in the edge portion 421E of the first molded layer 421. The remaining pattern material 440R may be obtained by allowing a portion of the pattern material layer 440L (see FIG. 12B) deposited on an almost vertical edge portion 421E of the first molded layer 421 to remain on the inclined edge portion 421E of the first molded layer 421 even after the CMP process. Accordingly, the remaining pattern material 440R may include the same material as the first nanoprism pattern NP1.

As illustrated in FIGS. 16 and 17, the above-described embodiments may be implemented in a form in which various embodiments are combined.

According to the one or more embodiments described above, in an image sensor having a meta-optical structure, defects (such as undercuts, peeling, cracks, or the like) occurring in a composite film (a multilayer film of the meta-optical structure and/or an insulating layer below the meta-optical structure) exposed to a sidewall of an opening for a bonding pad may be prevented to improve the reliability of the image sensor.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An image sensor, comprising:
a stack structure comprising an active pixel region comprising a plurality of pixels, a pad region on at least one side of the active pixel region, and a first substrate having a first surface and a second surface that is opposite to the first surface, the first substrate comprising a plurality of photoelectric conversion regions respectively corresponding to the plurality of pixels;
a meta-optical structure on the first surface of the first substrate and comprising a plurality of dielectric layers on the first surface of the first substrate, and nanoprism patterns in at least one dielectric layer of the plurality of dielectric layers and in the active pixel region;
a pad opening in the meta-optical structure; and
a passivation layer at least partially covering a sidewall of the pad opening.

2. The image sensor of claim 1, wherein the plurality of dielectric layers comprise a base dielectric layer and at least one molded layer comprising the nanoprism patterns.

3. The image sensor of claim 2, wherein the meta-optical structure further comprises an anti-reflection layer on the at least one molded layer.

4. The image sensor of claim 3, wherein the passivation layer comprises a material that is the same as a material of the anti-reflection layer.

5. The image sensor of claim 4, wherein the anti-reflection layer comprises a plurality of holes, and
wherein an upper end of the passivation layer that is on the sidewall of the pad opening comprises a rounded portion.

6. The image sensor of claim 2, wherein the nanoprism patterns comprise first nanoprism patterns and second nanoprism patterns, and wherein the at least one molded layer comprises a first molded layer having the first nanoprism patterns therein, and a second molded layer on the first molded layer and having the second nanoprism patterns therein.

7. The image sensor of claim 6, wherein the first molded layer comprises an edge portion spaced apart from the sidewall of the pad opening, and the second molded layer covers the edge portion of the first molded layer.

8. The image sensor of claim 1, further comprising a transparent planarization layer between the first surface of the first substrate and the meta-optical structure, and comprising an edge portion spaced apart from the pad opening,
wherein the edge portion of the transparent planarization layer is covered by at least one of the plurality of dielectric layers.

9. The image sensor of claim 8, wherein the transparent planarization layer comprises an organic material.

10. The image sensor of claim 1, wherein the pad opening extends to an edge of the first substrate.

11. The image sensor of claim 1, wherein the bonding pad is on the first surface of the first substrate.

12. The image sensor of claim 1, wherein the stack structure further comprises a second substrate,
wherein the pad opening extends through the first substrate in the pad region,
wherein the bonding pad is in a region of the second substrate exposed by the pad opening, and
wherein the passivation layer extends to cover a sidewall of the first substrate exposed by the pad opening.

13. An image sensor, comprising:
a stack structure comprising an active pixel region comprising a plurality of pixels, a pad region on at least one side of the active pixel region, a first substrate having a first surface and comprising a plurality of photoelectric conversion regions respectively corresponding to the plurality of pixels;
a meta-optical structure on the first surface of the first substrate and comprising a plurality of dielectric layers on the first surface of the first substrate, and nanoprism patterns in at least one dielectric layer of the plurality of dielectric layers and in the active pixel region; and
a pad opening in the meta-optical structure,
wherein the nanoprism patterns comprise a first nanoprism pattern and a second nanoprism pattern,
wherein the plurality of dielectric layers comprise a first molded layer having the first nanoprism pattern therein, and a second molded layer on the first molded layer and having the second nanoprism pattern therein,
wherein the first molded layer comprises a first edge portion spaced apart from a sidewall of the pad opening, and
wherein the second molded layer covers the first edge portion of the first molded layer.

14. The image sensor of claim 13, further comprising a pattern material in the first edge portion of the first molded layer, wherein a material of the pattern material is the same as a material of the first nanoprism pattern, and
wherein the second molded layer covers the first edge portion of the first molded layer and the pattern material.

15. The image sensor of claim 13, wherein the second molded layer comprises a second edge portion spaced apart from the sidewall of the pad opening.

16. The image sensor of claim 13, further comprising a passivation layer on the sidewall of the pad opening and covering portions of the plurality of dielectric layers,
wherein the meta-optical structure further comprises an anti-reflection layer on the second molded layer, and
wherein the passivation layer comprises a material that is the same as a material of the anti-reflection layer.

17. An image sensor, comprising:
a stack structure comprising an active pixel region comprising a plurality of pixels, a pad region on at least one side of the active pixel region, and a first substrate having a first surface and comprising a plurality of photoelectric conversion regions respectively corresponding to the plurality of pixels;
a meta-optical structure on the first surface of the first substrate and comprising a plurality of dielectric layers on the first surface of the first substrate, and nanoprism patterns in at least one dielectric layer of the plurality of dielectric layers and in the active pixel region;
a pad opening in the meta-optical structure; and
a transparent planarization layer between the first surface of the first substrate and the meta-optical structure, the transparent planarization layer comprising an edge portion spaced apart from a sidewall of the pad opening, wherein the edge portion of the transparent planarization layer is covered by at least one of the plurality of dielectric layers.

18. The image sensor of claim 17, wherein the nanoprism patterns comprise first nanoprism patterns and second nanoprism patterns, wherein the plurality of dielectric layers comprise:
a base dielectric layer on the transparent planarization layer;
a first molded layer on the base dielectric layer and comprising the first nanoprism patterns in the active pixel region; and
a second molded layer on the first molded layer and comprising the second nanoprism patterns,
wherein the edge portion of the transparent planarization layer is covered by the base dielectric layer, and
wherein the base dielectric layer comprises a portion exposed at the sidewall of the pad opening.

19. The image sensor of claim 18, wherein the first molded layer comprises a first edge portion spaced apart from the pad opening, and the second molded layer covers the first edge portion of the first molded layer.

20. The image sensor of claim 18, wherein the meta-optical structure further comprises an anti-reflection layer on the second molded layer, and
wherein the image sensor further comprises a passivation layer on the sidewall of the pad opening and covering portions of the plurality of dielectric layers, the passivation layer comprising a material that is the same as a material of the anti-reflection layer.
